(19) United States
(12) Patent Application Publication
(10) Pub. No.: US 2024/0006313 A1
(43) Pub. Date: Jan. 4, 2024

(54) SELF-ALIGNED BACKSIDE CONNECTIONS FOR TRANSISTORS

(71) Applicant: International Business Machines Corporation, Armonk, NY (US)

(72) Inventors: Brent A. Anderson, Jericho, VT (US); Ruilong Xie, Niskayuna, NY (US); Junli Wang, Slingerlands, NY (US); Albert M. Chu, Nashua, NH (US)

(21) Appl. No.: 17/809,621

(22) Filed: Jun. 29, 2022

(51) Int. Cl. H01L 23/528; H01L 27/088; H01L 29/06; H01L 29/423; H01L 29/417; H01L 29/786; H01L 29/775; H01L 21/02; H01L 21/8234; H01L 29/66

(52) U.S. Cl. CPC H01L 23/5286; H01L 27/088; H01L 29/0673; H01L 29/42392; H01L 29/41733; H01L 29/78696; H01L 29/775; H01L 21/02603; H01L 21/823412; H01L 21/823418; H01L 21/823481; H01L 21/823475; H01L 29/66742; H01L 29/66439

(57) ABSTRACT

Provided is a semiconductor device. The semiconductor device comprises a plurality of logic devices. The logic devices have frontside wiring. The semiconductor device further comprises a backside power delivery network (BSPDN). The semiconductor device further comprises a connection between the BSPDN and the bottom of a source/drain epitaxy of a logic device. The connection is self-aligned on at least two sides.

### BACKGROUND

The present invention relates in general to semiconductor fabrication methods and resulting structures. More specifically, the present invention relates to backside interconnects providing power delivery to field-effect-transistors of semiconductor devices and methods of forming the same.

In an integrated circuit, transistors such as metal oxide semiconductor field effect transistors (MOSFETs) have a source and a drain that are formed in an active region of a semiconductor layer by implanting n-type or p-type impurities in the layer of semiconductor material. Disposed between the source and the drain is a channel (or body) region. Disposed above the body region is a gate electrode. The gate electrode and the body are spaced apart by a gate dielectric layer. Complementary metal oxide semiconductor (CMOS) is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode via a power distribution network.

### SUMMARY

Embodiments of the present invention include fabrication methods and the corresponding structures. Some embodiments of the present disclosure include a semiconductor device. The semiconductor device comprises a plurality of logic devices. The logic devices have frontside wiring. The semiconductor device further comprises a backside power delivery network (BSPDN). The semiconductor device further comprises a connection between the BSPDN and the bottom of a source/drain epitaxy of a logic device. The connection is self-aligned on at least two sides.

Further embodiments of the present disclosure include another semiconductor device. The semiconductor device comprises a plurality of nanosheet transistors. Each nanosheet transistor includes a source/drain epitaxy. The semiconductor device further comprises a backside power delivery network (BSPDN). The semiconductor device further comprises a connection between the BSPDN and the bottom of a source/drain epitaxy of a nanosheet transistor. The connection is self-aligned on at least two sides. The semiconductor device further comprises a back-end-of-line (BEOL) structure. The semiconductor device further comprises one or more BEOL contacts. Each BEOL contact connects a source-drain epitaxy of a nanosheet transistor to the BEOL

Additional embodiments of the present disclosure include a fabrication method, system, and computer program product. The fabrication method comprises forming a BOX layer on top of a substrate. The method further comprises forming an etch stop layer in the BOX layer. The method further comprises patterning fin regions and filling with dielectric composite stack to create one or more isolation regions. The one or more isolation regions define a pattern for one or more self-aligned backside connections that are to be formed. The method further comprises forming one or more nanosheet transistors in the dielectric composite stack. The method further comprises removing the substrate to expose the one or more isolation regions. The method further comprises selectively removing the BOX layer to expose the bottom of a source/drain epitaxy of at least one nanosheet transistor. The method further comprises forming metal rails with connections to the bottom of the source/drain epitaxy in the region opened up by removal of the portion of the BOX layer.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 depicts a plan view of an example nanosheet transistor indicating a Y cross-section location and an X cross section location for the following figures, in accordance with embodiments of the present disclosure.

FIG. 2A illustrates a cross-sectional view of an example semiconductor device at an intermediate stage in the fabrication process, in accordance with embodiments of the present disclosure.

FIG. 2B illustrates a cross-sectional view of the example of the semiconductor device of FIG. 2A following the performance of additional fabrication operations, in accordance with embodiments of the present disclosure.

FIG. 2C illustrates a cross-sectional view of the example of the semiconductor device of FIG. 2B following the performance of additional fabrication operations, in accordance with embodiments of the present disclosure.

FIG. 2D illustrates a cross-sectional view of the example of the semiconductor device of FIG. 2C following the performance of additional fabrication operations, in accordance with embodiments of the present disclosure.

FIG. 2E illustrates a cross-sectional view of the example of the semiconductor device of FIG. 2D following the performance of additional fabrication operations, in accordance with embodiments of the present disclosure.

FIG. 2F illustrates a cross-sectional view of the example of the semiconductor device of FIG. 2E following the performance of additional fabrication operations, in accordance with embodiments of the present disclosure.

FIG. 2G illustrates a cross-sectional view of the example of the semiconductor device of FIG. 2F following the performance of additional fabrication operations, in accordance with embodiments of the present disclosure.

FIG. 2H illustrates a cross-sectional view of the example of the semiconductor device of FIG. 2G following the performance of additional fabrication operations, in accordance with embodiments of the present disclosure.

FIG. 2I illustrates a cross-sectional view of the example of the semiconductor device of FIG. 2H following the performance of additional fabrication operations, in accordance with embodiments of the present disclosure.

FIG. 2J illustrates a cross-sectional view of the example of the semiconductor device of FIG. 2I following the performance of additional fabrication operations, in accordance with embodiments of the present disclosure.

FIG. 2K illustrates a cross-sectional view of the example of the semiconductor device of FIG. 2J following the performance of additional fabrication operations, in accordance with embodiments of the present disclosure.

FIG. 3A illustrates a cross-sectional view of an example semiconductor device at an intermediate stage in the fabrication process, in accordance with embodiments of the present disclosure.

FIG. 3B illustrates a cross-sectional view of the example of the semiconductor device of FIG. 3A following the performance of additional fabrication operations, in accordance with embodiments of the present disclosure.

FIG. 3C illustrates a cross-sectional view of the example of the semiconductor device of FIG. 3B following the performance of additional fabrication operations, in accordance with embodiments of the present disclosure.

FIG. 4A illustrates a cross-sectional view of an example semiconductor device at an intermediate stage in the fabrication process, in accordance with embodiments of the present disclosure.

FIG. 4B illustrates a cross-sectional view of the example of the semiconductor device of FIG. 4A following the performance of additional fabrication operations, in accordance with embodiments of the present disclosure.

FIG. 5A illustrates a cross-sectional view of an example semiconductor device at an intermediate stage in the fabrication process, in accordance with embodiments of the present disclosure.

FIG. 5B illustrates a cross-sectional view of the example of the semiconductor device of FIG. 5A following the performance of additional fabrication operations, in accordance with embodiments of the present disclosure.

FIG. 5C illustrates a cross-sectional view of the example of the semiconductor device of FIG. 5B following the performance of additional fabrication operations, in accordance with embodiments of the present disclosure.

FIG. 5D illustrates a cross-sectional view of the example of the semiconductor device of FIG. 5C following the performance of additional fabrication operations, in accordance with embodiments of the present disclosure.

FIG. 5E illustrates a cross-sectional view of the example of the semiconductor device of FIG. 5D following the performance of additional fabrication operations, in accordance with embodiments of the present disclosure.

FIG. 5F illustrates a cross-sectional view of the example of the semiconductor device of FIG. 5E following the performance of additional fabrication operations, in accordance with embodiments of the present disclosure.

FIG. 5G illustrates a cross-sectional view of the example of the semiconductor device of FIG. 5F following the performance of additional fabrication operations, in accordance with embodiments of the present disclosure.

FIG. 5H illustrates a cross-sectional view of the example of the semiconductor device of FIG. 5G following the performance of additional fabrication operations, in accordance with embodiments of the present disclosure.

FIG. 5I illustrates a cross-sectional view of the example of the semiconductor device of FIG. 5H following the performance of additional fabrication operations, in accordance with embodiments of the present disclosure.

FIG. 6 illustrates a cross-sectional view of an example semiconductor device at an intermediate stage in the fabrication process, in accordance with embodiments of the present disclosure.

FIG. 7A illustrates a cross-sectional view of an example semiconductor device at an intermediate stage in the fabrication process, in accordance with embodiments of the present disclosure.

FIG. 7B illustrates a cross-sectional view of the example of the semiconductor device of FIG. 7A following the performance of additional fabrication operations, in accordance with embodiments of the present disclosure.

FIG. 7C illustrates a cross-sectional view of the example of the semiconductor device of FIG. 7B following the performance of additional fabrication operations, in accordance with embodiments of the present disclosure.

FIG. 7D illustrates a cross-sectional view of the example of the semiconductor device of FIG. 7C following the performance of additional fabrication operations, in accordance with embodiments of the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the invention.

### DETAILED DESCRIPTION

Embodiments of the present invention are generally directed to semiconductor fabrication methods and resulting structures, and more particularly to backside interconnects providing power delivery to field-effect-transistors of semiconductor devices and methods of making the same. While the present disclosure is not necessarily limited to such applications, various aspects of the disclosure may be appreciated through a discussion of various examples using this context.

Various embodiments of the present disclosure are described herein with reference to the related drawings, where like numbers refer to the same component. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

As used herein, the articles “a” and “an” preceding an element or component are intended to be nonrestrictive regarding the number of instances (i.e. occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects in any and all possible combinations as described in the specification and the claims.

The terms “about,” “substantially,” “approximately,” “slightly less than,” and variations thereof, are intended to include the degree of error associated with measurement of the particular quantity based upon the equipment available at the time of filing the application. For example, “about” can include a range of ±8% or 5%, or 2% of a given value.

For purposes of the description hereinafter, when a first surface is referred to as being arranged “opposite” to a second surface, the first surface is different from the second surface, and the first surface is spaced apart from the second surface. For instances in which the surfaces are substantially planar, the first surface is substantially parallel to the second surface.

It is to be understood that as used herein, “an embodiment” means one or more embodiments that share a common aspect. For example, “a first embodiment” may include one or more embodiments that are related in that they all share a first common aspect, function, and/or feature. Likewise, “a second embodiment” may include one or more embodiments that are related in that they all share a second common aspect, function, and/or feature. Furthermore, a particular embodiment that has both the first common aspect, function, and/or feature and the second common aspect, function, and/or feature may be considered to be both a first embodiment and a second embodiment.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, an integrated circuit (IC) is a set of electronic circuits on one small flat piece (or “chip”) of semiconductor material. More specifically, large numbers of tiny transistors can be integrated into a small chip, and interconnects can be used to connect two or more circuit elements (such as transistors) on the chip together electrically. Interconnects can also be used to provide power to the transistors through a power distribution network (PDN) that utilizes buried power rails and via-to-buried power rails (VBPRs). This results in circuits that are orders of magnitude smaller, faster, and less expensive than those constructed of discrete electronic components.

The field-effect transistor (FET) is a type of transistor that uses an electric field to control the flow of current in a semiconductor. FETs are devices with three terminals: a source, a gate, and a drain. FETs control the flow of current by the application of a voltage to the gate, which in turn alters the conductivity between the drain and source. More specifically, the FET controls the flow of electrons (or holes) from the source to drain by affecting the size and shape of a conductive channel created and influenced by voltage (or lack of voltage) applied across the gate and source terminals. (For simplicity, this discussion assumes that the body and source are connected.) This conductive channel is the stream through which electrons flow from source to drain.

FETs are also known as unipolar transistors since they involve single-carrier-type operation. In other words, a FET uses either electrons or holes as charge carriers in its operation, but not both. The source/drain of a FET is doped to produce either an n-type semiconductor (in which case the FET can be referred to as an NFET) or a p-type semiconductor (in which case the FET can be referred to as a PFET). When the voltage applied to the gate of the FET is larger than the threshold voltage, the charge carriers in the channel region of the FET are built up, which activates the FET (e.g., allowing current to flow between the source and the drain).

Many different types of field effect transistors exist. A gate-all-around (GAA) FET is a non-planar (3D) transistor designed such that the gate material surrounds the channel region on all sides. Accordingly, the contact between the gate and the channel is increased, which provides better electrical control over the channel. A GAAFET can be a PFET or an NFET. A gate-all-around n-type semiconductor may also be referred to herein as a GAA NFET. Similarly, a gate-all-around p-type semiconductor may also be referred to herein as a GAA PFET.

A nanosheet transistor is a type of GAA transistor in which one or more sheets of semiconductor material (e.g., Si) are used to create the transistor channels which are surrounded by the gate. As such, the gate is able to surround each sheet on all sides, thereby increasing the contact between the gate and the channel. Furthermore, the more nanosheets used by a transistor, the more contact surface area the gate has with the channel. This provides excellent control of current leakage within the transistor. Nanosheet transistors may be vertically aligned, with a bottom source/drain disposed below the nanosheets (e.g., between the nanosheets and the substrate) and a top source/drain disposed on the top of the nanosheets (opposite the bottom source/drain), or they may be horizontally aligned (e.g., a horizontal-transport GAAFET), where the current travels from the source to the drain in a horizontal direction.

In some embodiments, nanosheets of opposite polarity are horizontally arranged side-by-side. For example, a GAA PFET can be arranged next to a GAA NFET. Once arranged, a pair including a GAA PFET and an GAA NFET can be functionally interconnected and utilized as a complementary metal-oxide-semiconductor (CMOS) cell. In a CMOS cell, complementary pairs of PFETs and NFETs are used for logic functions.

In integrated circuits, interconnects are structures that connect two or more circuit elements together electrically. In addition to providing the electrical connection to the front end devices (such as transistors), interconnects also go all the way back to the power delivery networks. Thus, interconnects, and their surrounding support components, may be considered back-end-of-line (BEOL) components. One common type of interconnect is a power rail.

In standard logic cells, power to the devices (e.g., transistors) is supplied to the source/drain contacts through power rails in BEOL metal layers. Power rails typically run across multiple adjacent cells. Accordingly, since power rails are typically used to supply power to a number of cells, the power rails are often implemented with much larger sizes (specifically, larger widths) compared to standard routing tracks/signal lines that are used within the cells. For example, a power rail can be up to three to four times larger than a normal routing line. Thus, power rails often take up significant amounts of area within cell design. The larger critical dimension of power rails is necessary to maintain an adequate resistance through the power rail to maintain adequate power distribution targets, including IR drop and frequency, within the device

Embodiments of the present disclosure include a semiconductor device comprising one or more logic devices (e.g., a complementary FET (CFET)). The logic device(s) includes frontside wiring. The semiconductor device further comprises a backside power delivery (or distribution) network (BSPDN). The semiconductor device further comprises a self-aligned (on at least two sides) connection from the BSPDN to the source/drain epitaxy bottom of the logic device(s).

In some embodiments, the self-aligned connection from the BSPDN to the source/drain epitaxy bottom is a power or ground rail (e.g., a buried power rail) that is connected to multiple source/drain epitaxy regions in the same library track. Additionally, or alternatively, the power or ground rails may be connected to multiple source/drain epitaxy regions in adjacent library tracks. The rail perimeter edges of the power or ground rail may be defined by frontside patterned isolation regions.

In some embodiments, the self-aligned connection from the BSPDN to the source/drain epitaxy bottom is a backside contact. Two sides of the contact may be defined by the frontside patterned isolation regions. A pre-formed BOX layer may separate contacts on two sides from the frontside patterned isolation regions.

In some embodiments, a pre-formed etch stop layer is on top of the power and ground rails. The location of the etch stop layer within the BOX can be optimized for capacitance vs. integration challenges, as needed.

In some embodiments, a bottom dielectric isolation (BDI) layer is formed below the gate. The BDI may be any suitable dielectric material including, for example, SiO2, SiOCN, SiOC, or SiBCN. The BDI may help protect against gate metal damage during the backside Si removal.

In some embodiments, the semiconductor device further comprises a bulk semiconductor region below the logic device region. The bulk semiconductor region may be at the same or similar level as the power and/or ground rails.

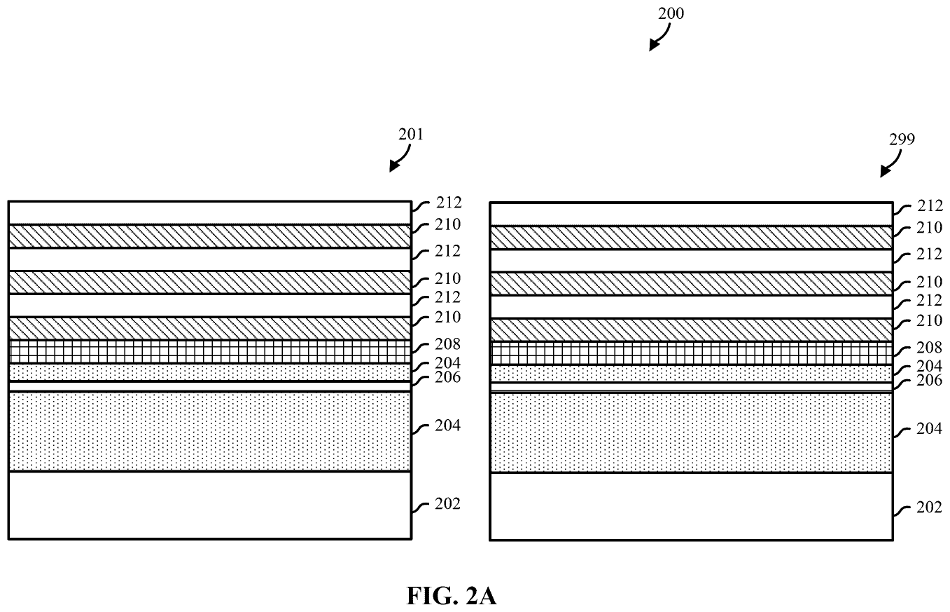

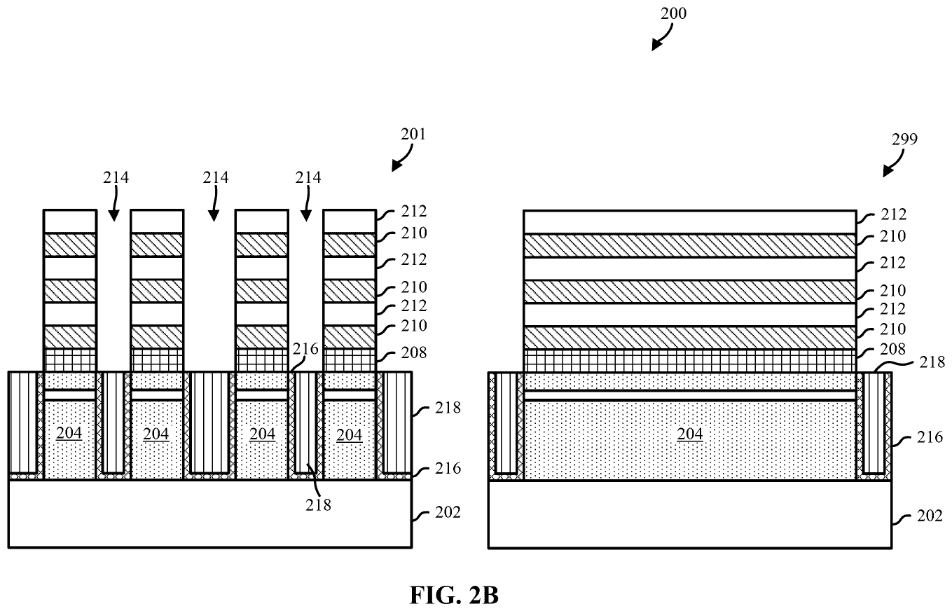

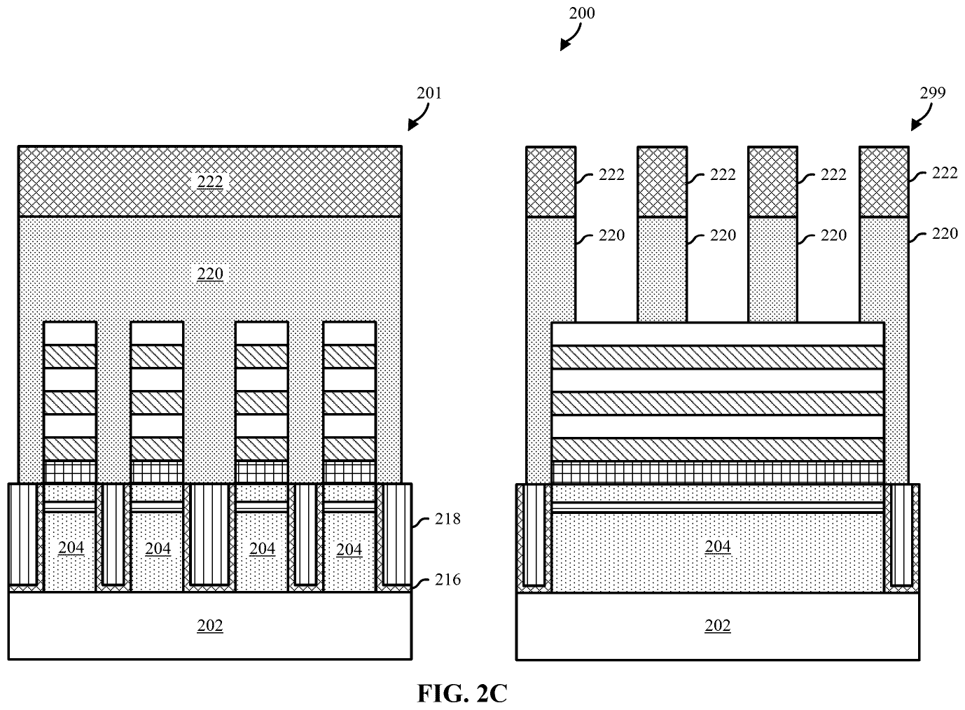

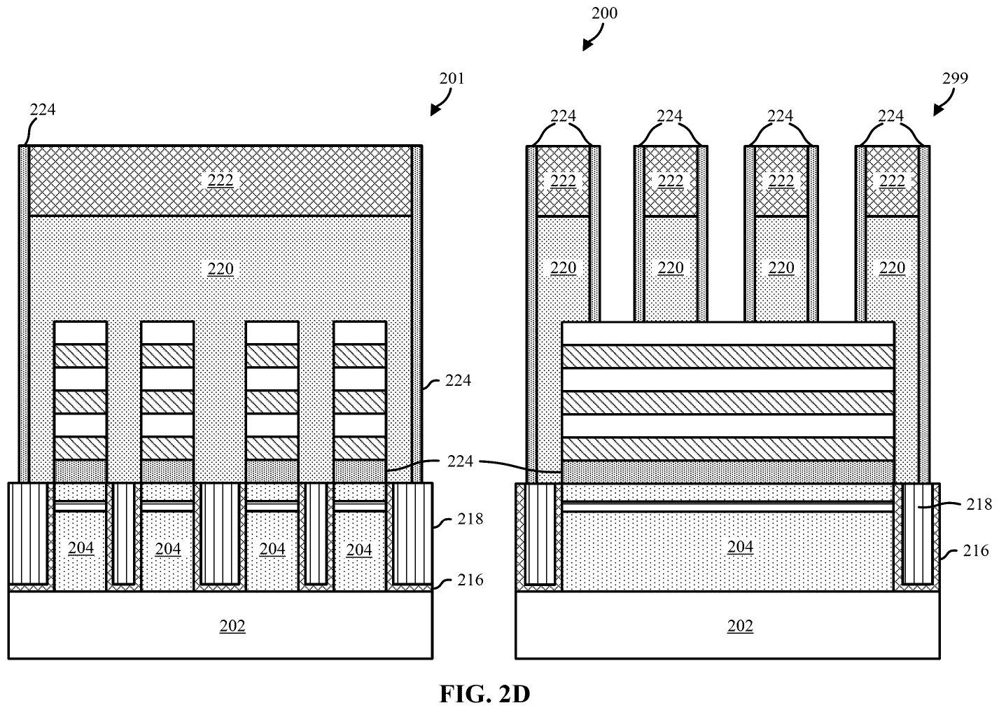

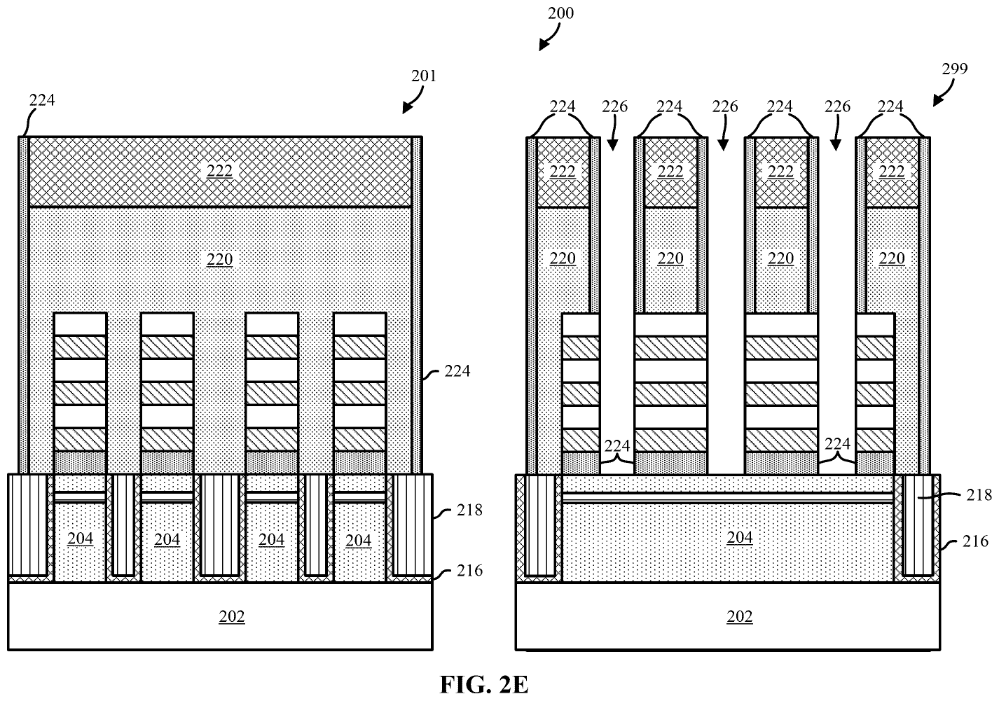

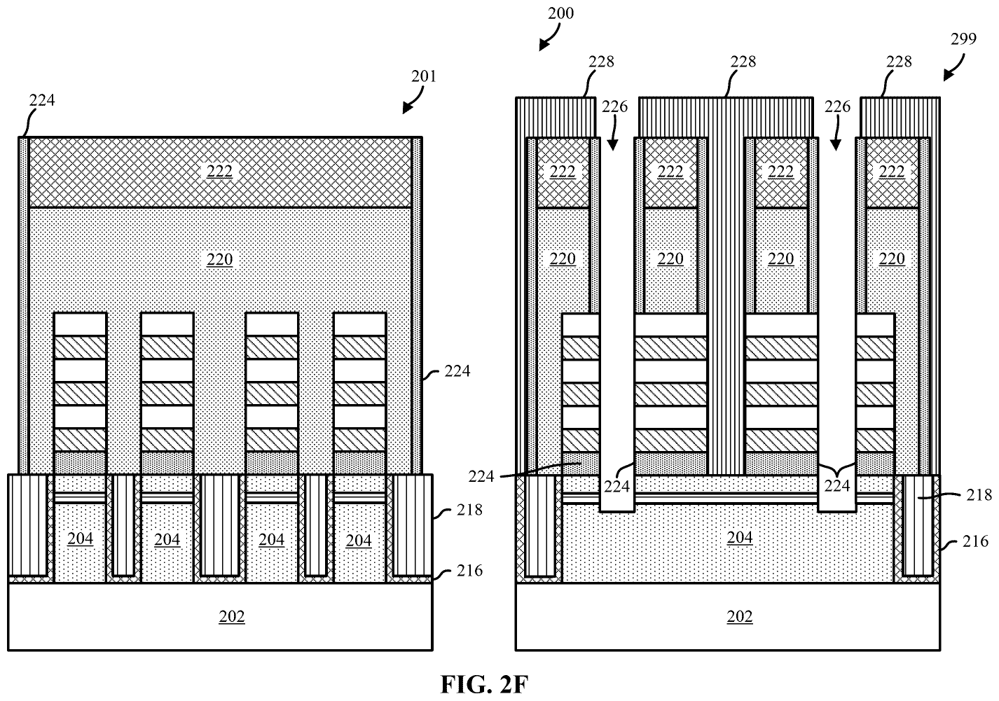

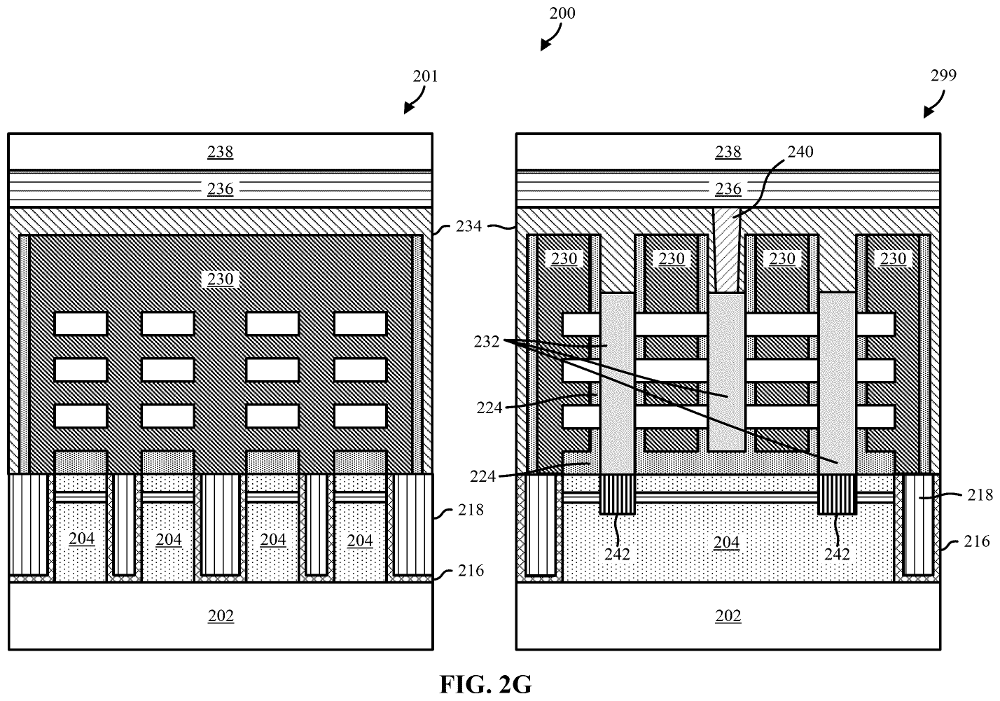

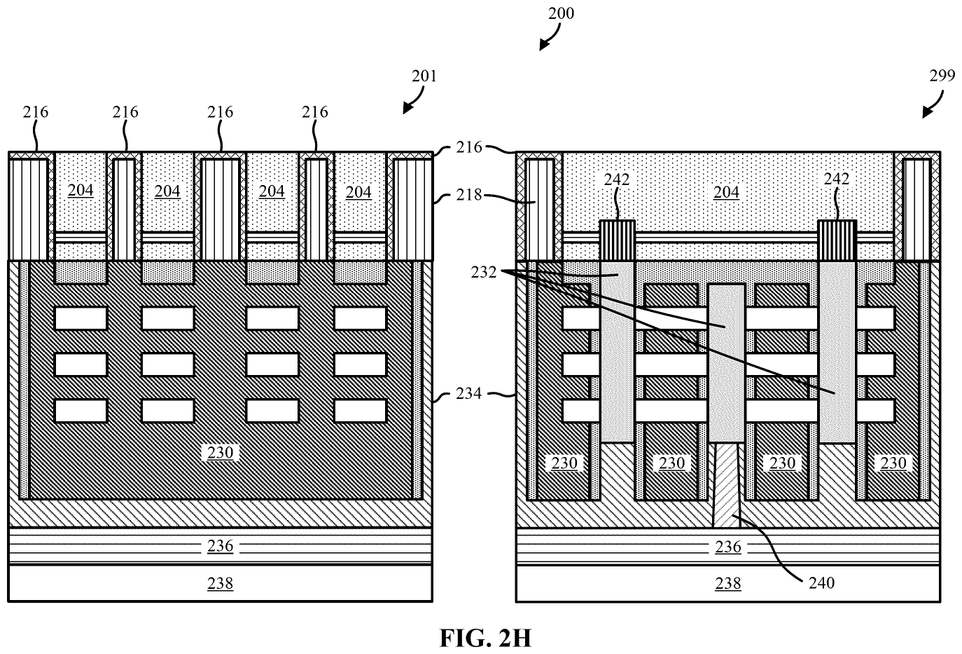

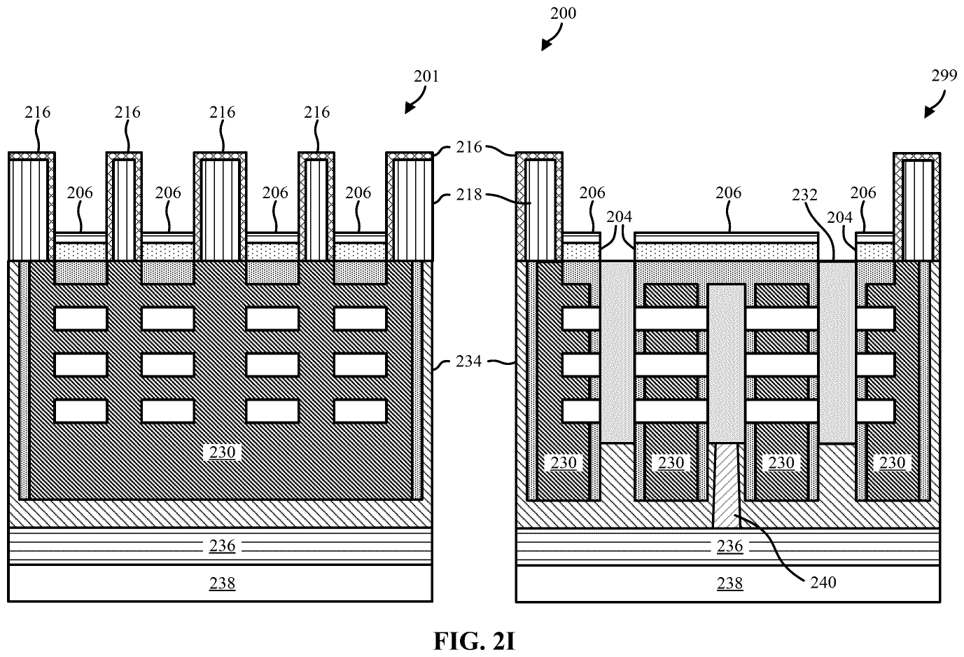

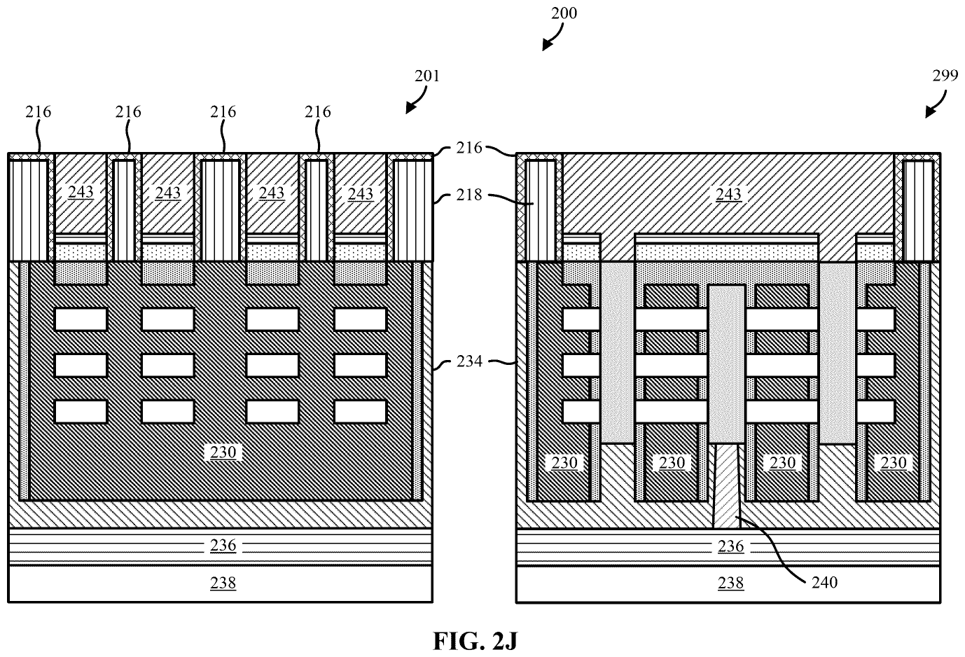

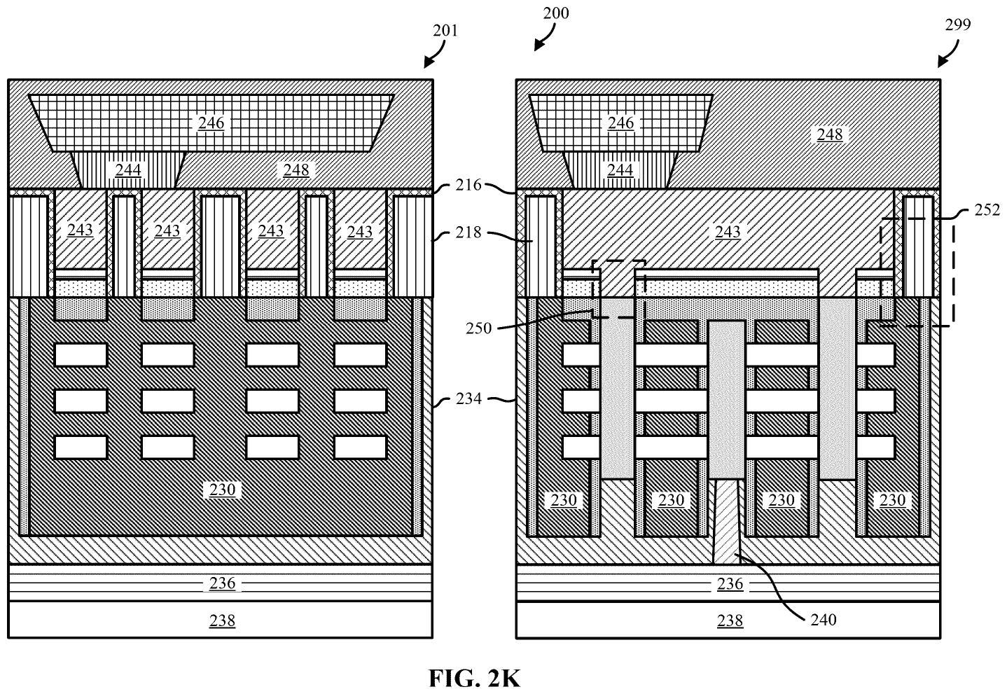

With the above in mind, numerous embodiments of the present disclosure are provided for illustrative purposes only. Each embodiment varies as to one or more stages of the semiconductor fabrication process, though the resulting semiconductor devices are functionally similar. In a first embodiment of the present disclosure, the backside contact metallization layers (i.e., the backside rails) of adjacent NFETs (and/or PFETs) are isolated from each other. The adjacent NFETs are nevertheless connected to the BSPDN using a single backside wire/via that bridges the adjacent metallization layers. FIGS. 2A-2K illustrate a process of fabricating an example of the first embodiment, with a completed FET in accordance with the first embodiment being shown in FIG. 2K.

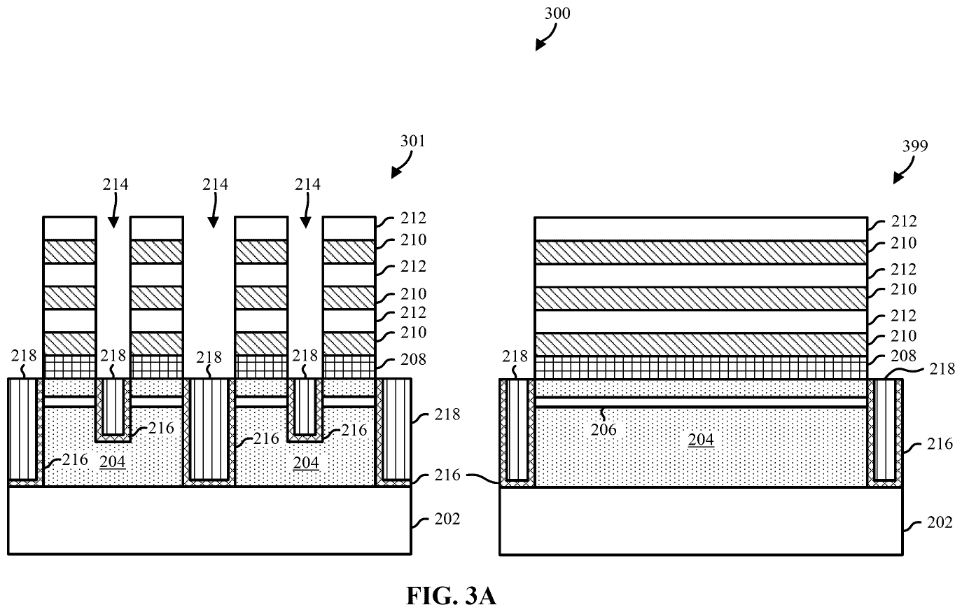

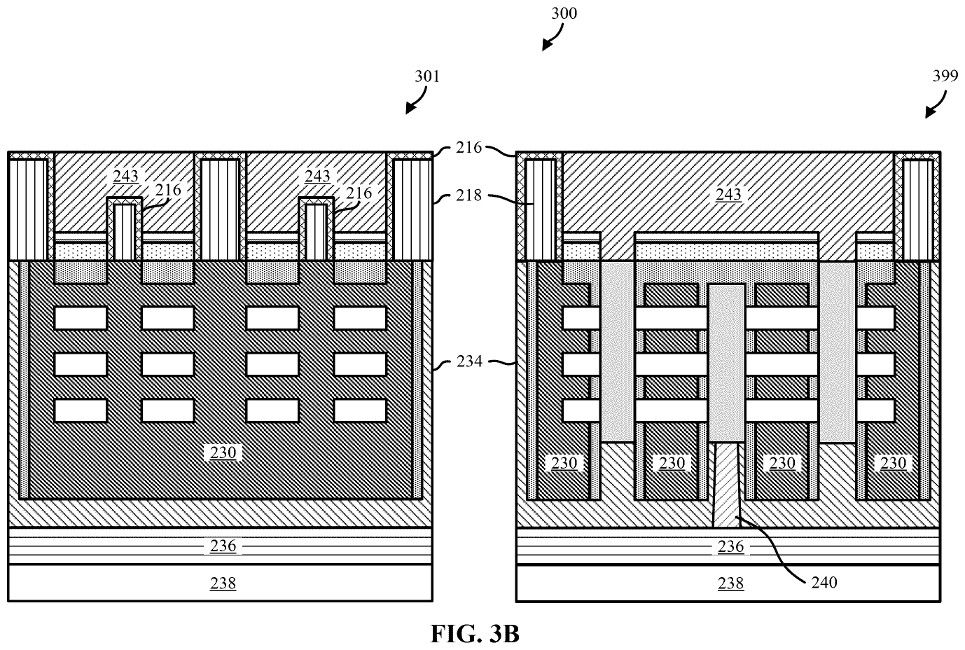

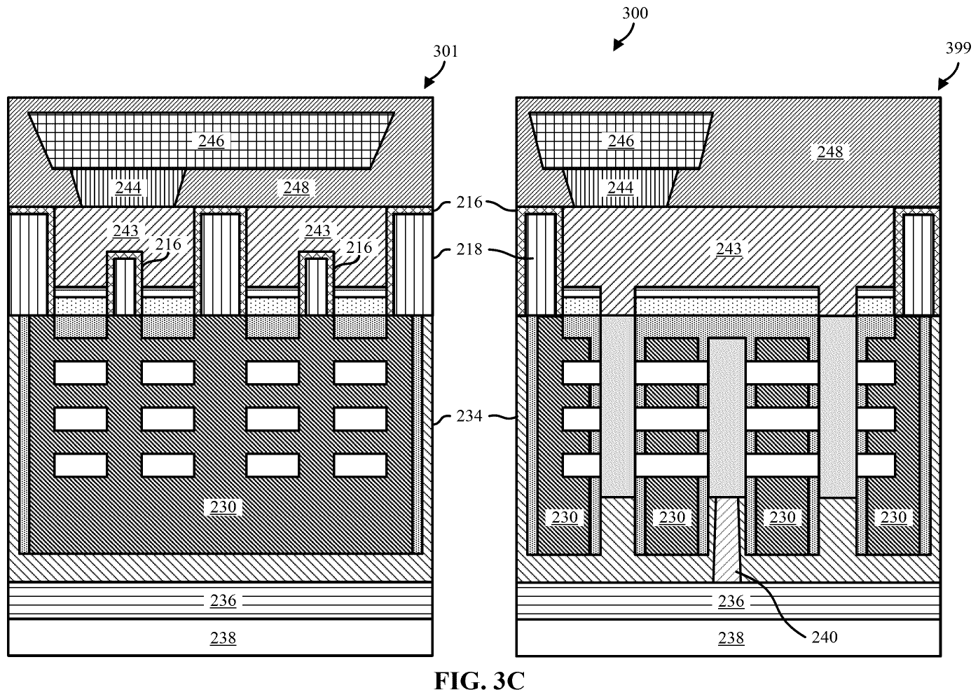

In a second embodiment of the present disclosure, the backside contact metallization layers (i.e., the backside rails) of adjacent FETs of the same polarity (e.g., adjacent NFETs and/or adjacent PFETs) are merged. Accordingly, the N-N and P-P regions of adjacent transistors have a shared backside rail. This may be done by utilizing shallow isolation regions during fabrication. The second embodiment may have a better process because of the connected N-N and P-P regions, but it is a more expensive process due to the additional masking step(s) required. FIGS. 3A-3C illustrate a few steps in the process of fabricating an example of the second embodiment, which otherwise follows a similar process to that shown with respect to FIGS. 2A-2K, with a completed FET in accordance with the second embodiment being shown in FIG. 3C.

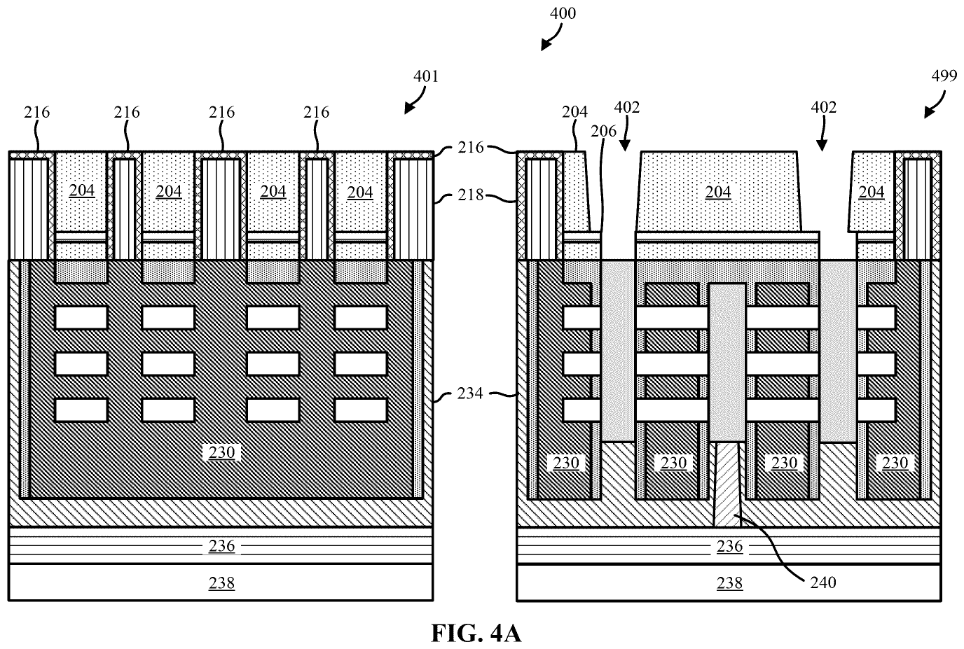

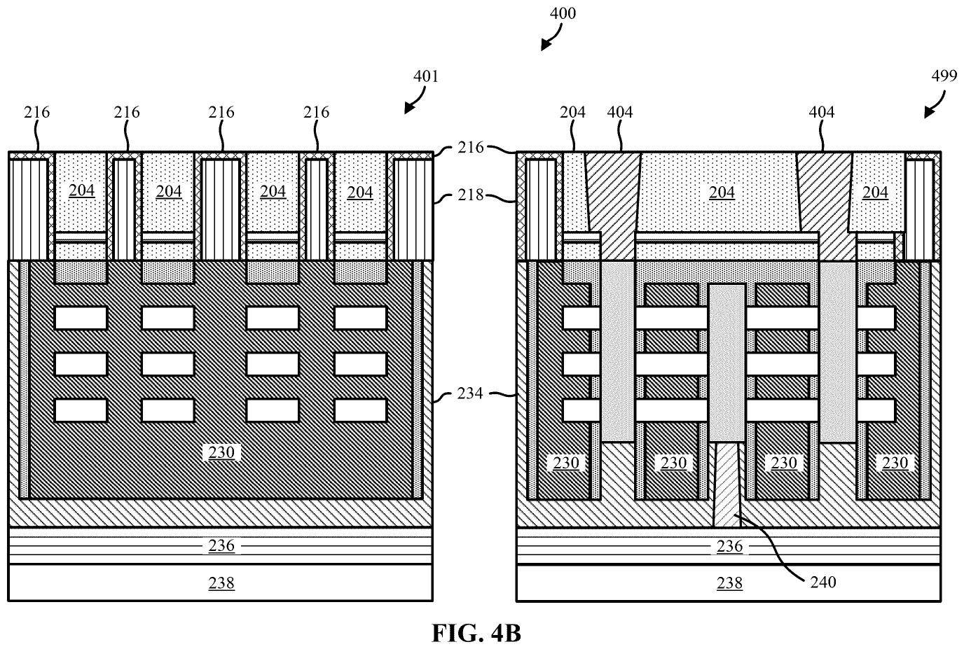

In a third embodiment of the present disclosure, the backside contacts in the source/drain epitaxy regions are isolated from each other. This may be done by selectively removing a portion of the backside BOX layer and temporary fill material, as opposed to removing all of the backside BOX layer per the first and second embodiments. FIGS. 4A-4B illustrate portions of a process of fabricating an example of the third embodiment, starting from an intermediate state. The intermediate state of the third embodiment is also an intermediate state of the first embodiment. In particular, the intermediate state for the third embodiment is the state shown in FIG. 2H.

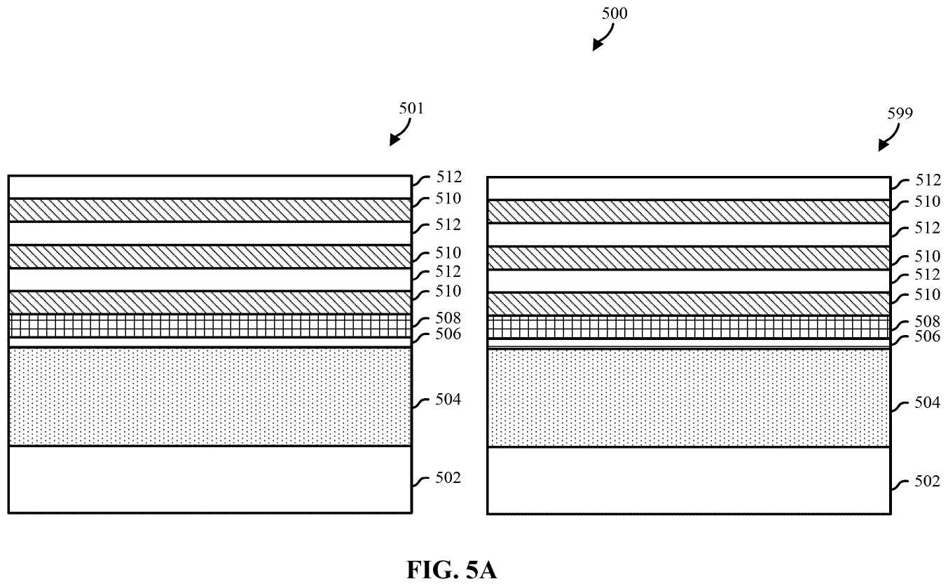

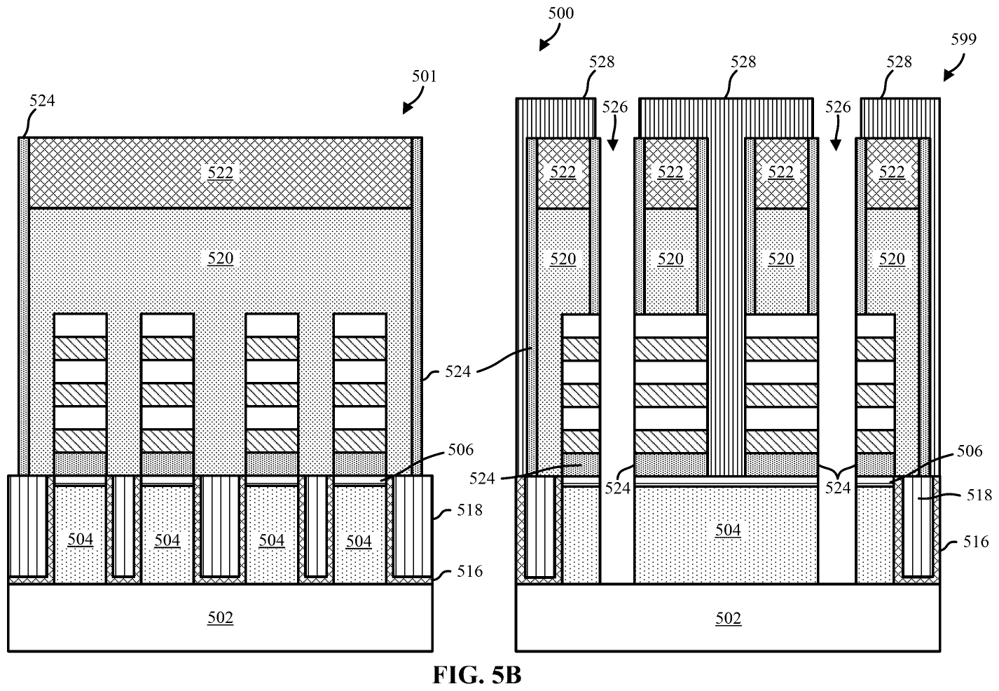

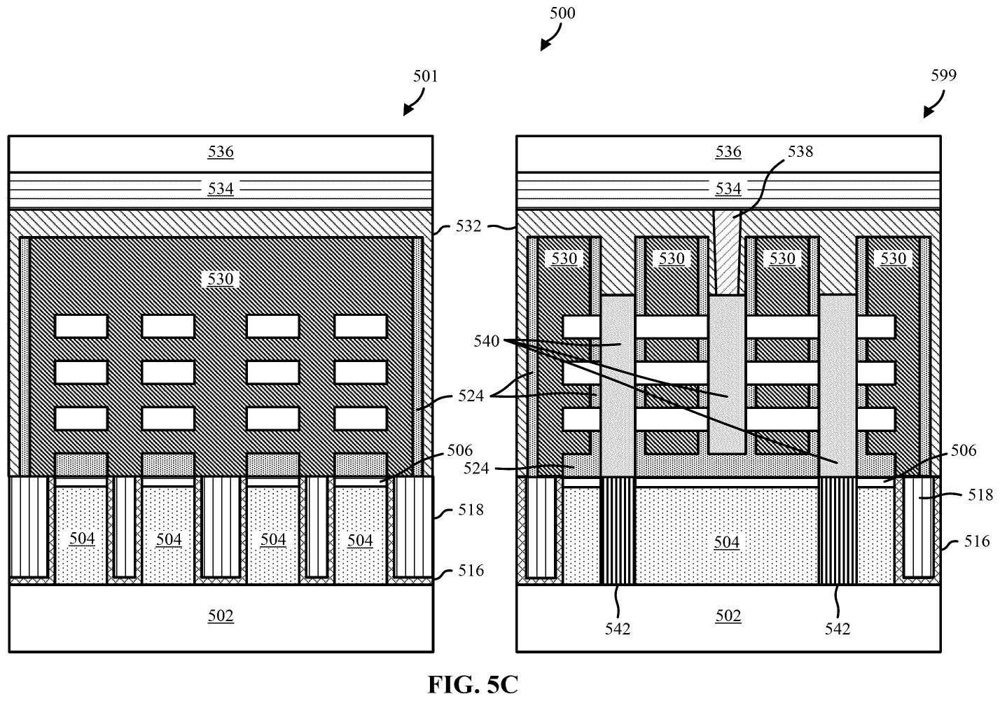

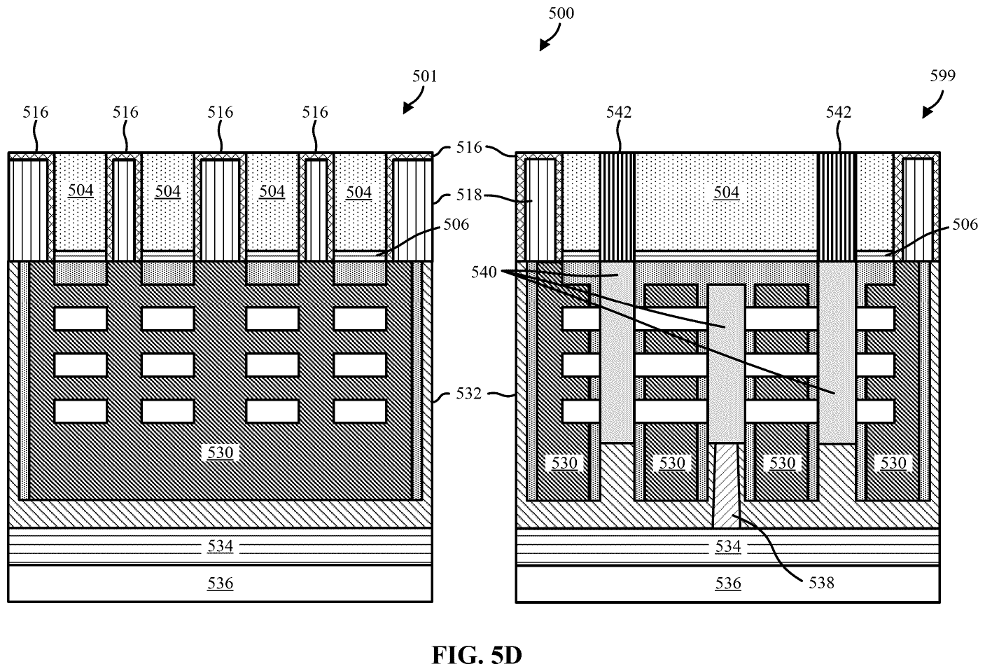

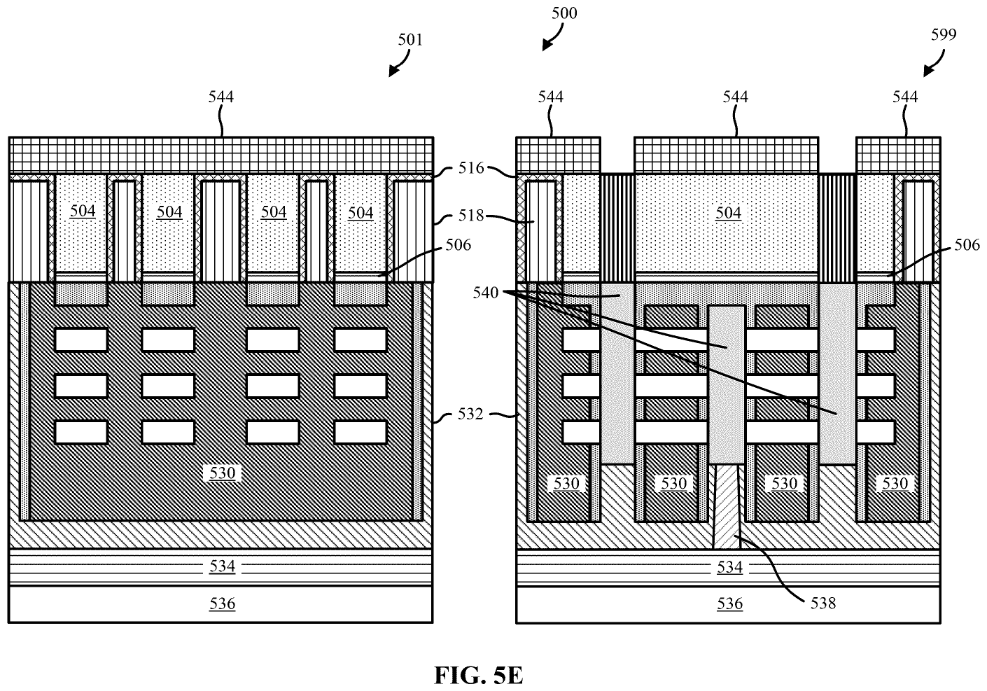

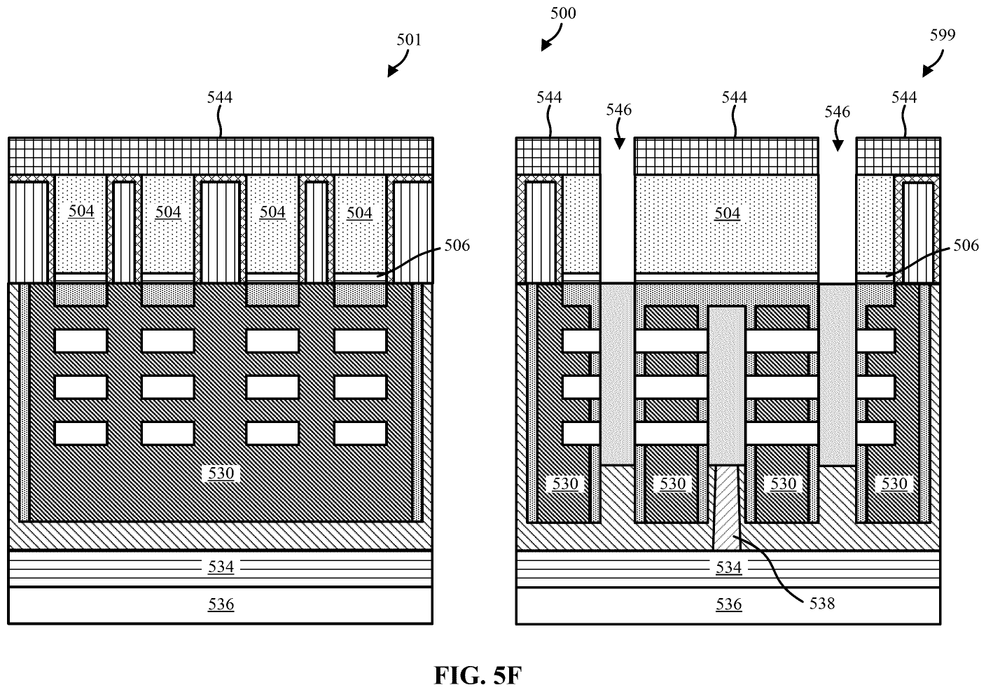

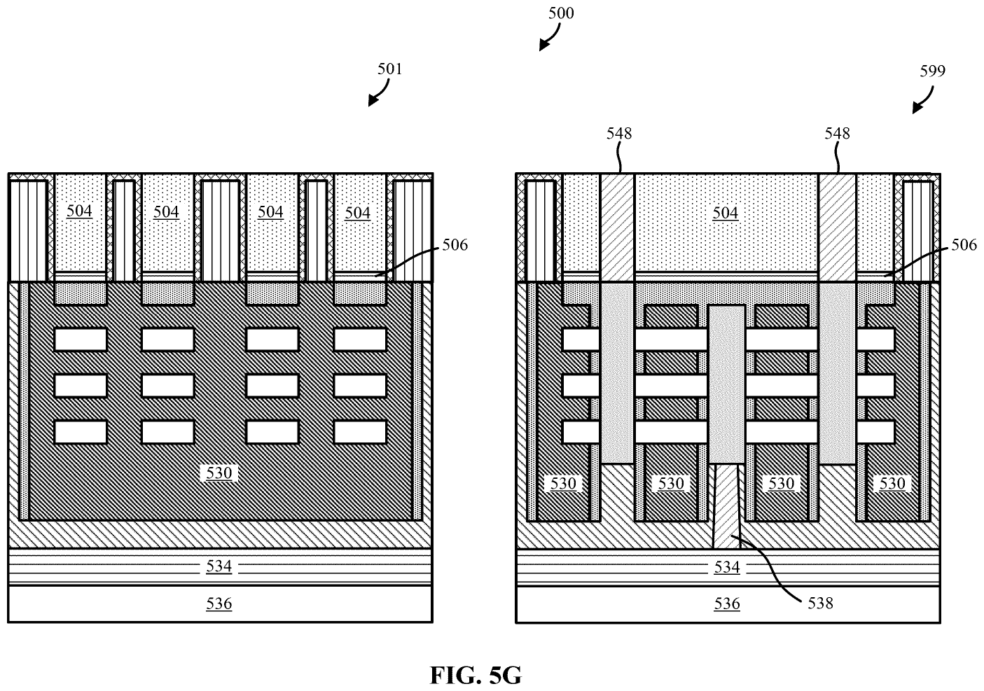

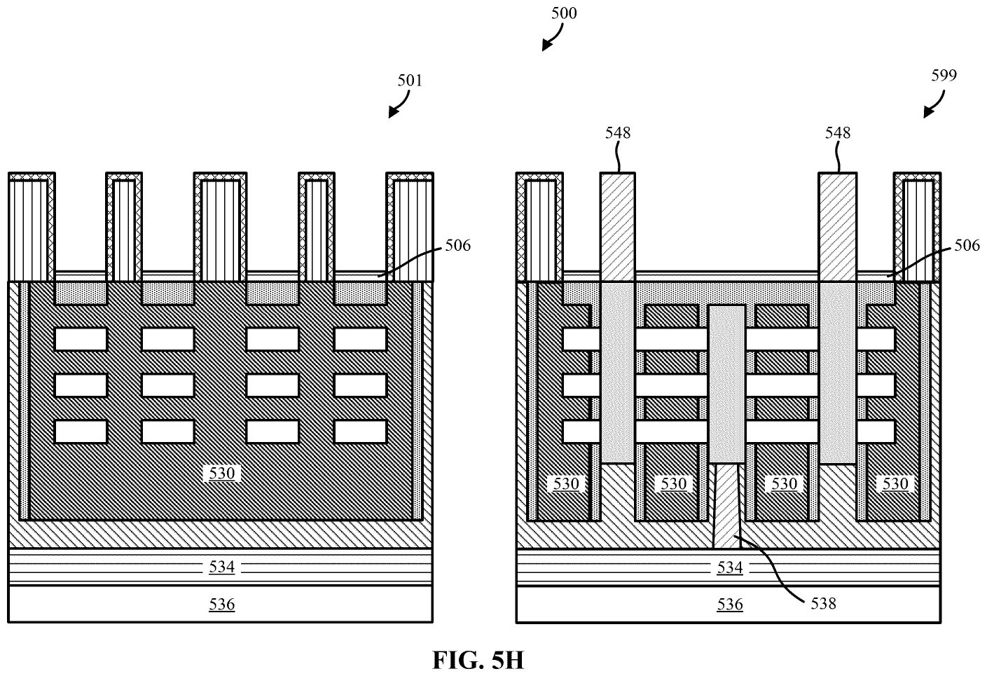

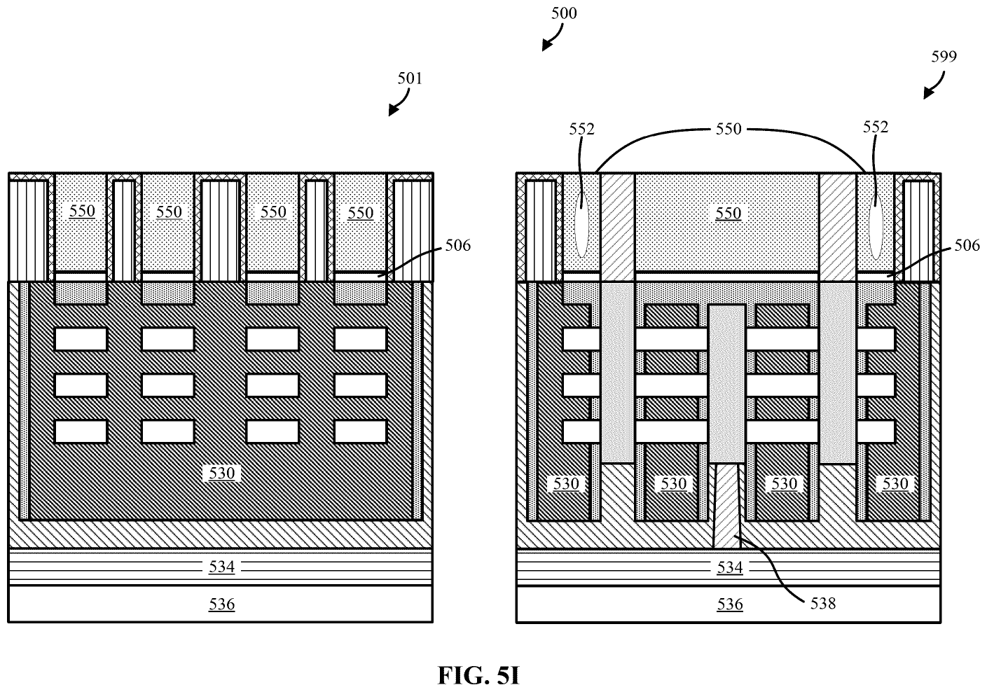

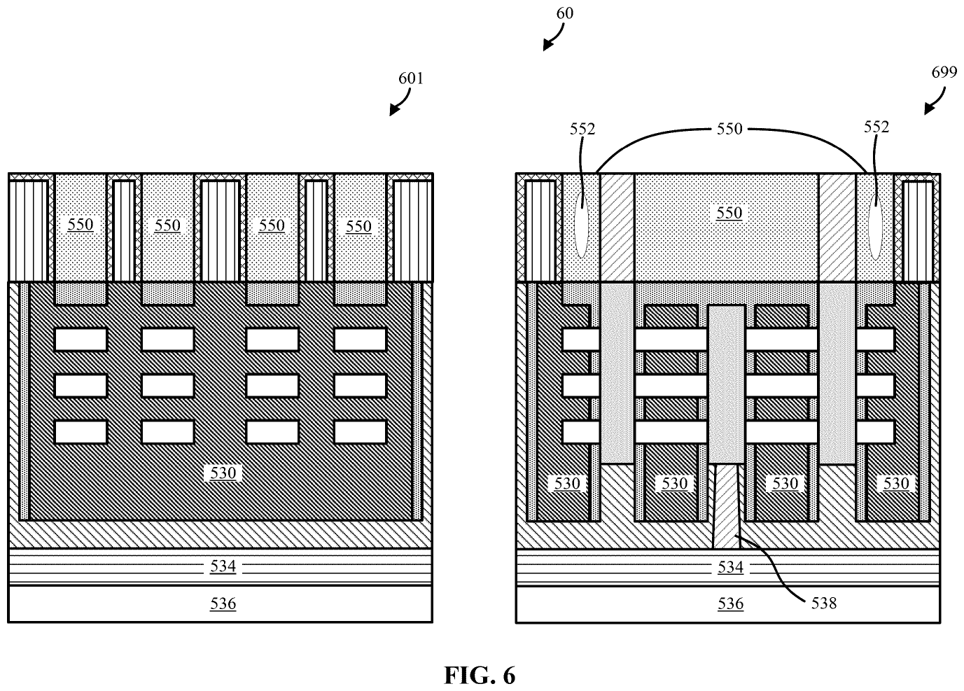

In a fourth embodiment of the present disclosure, the semiconductor device comprises a bulk substrate. FIGS. 5A-5I illustrate a process of fabricating an example of the fourth embodiment. FIG. 6 illustrates an example of the fourth embodiment in which the etch stop is completely removed.

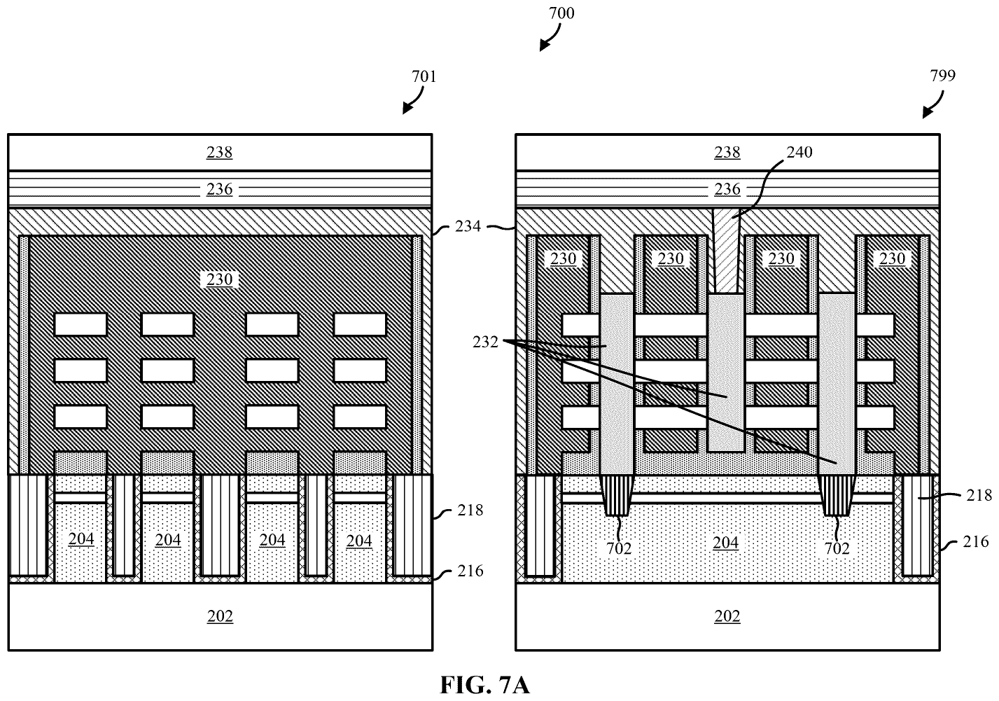

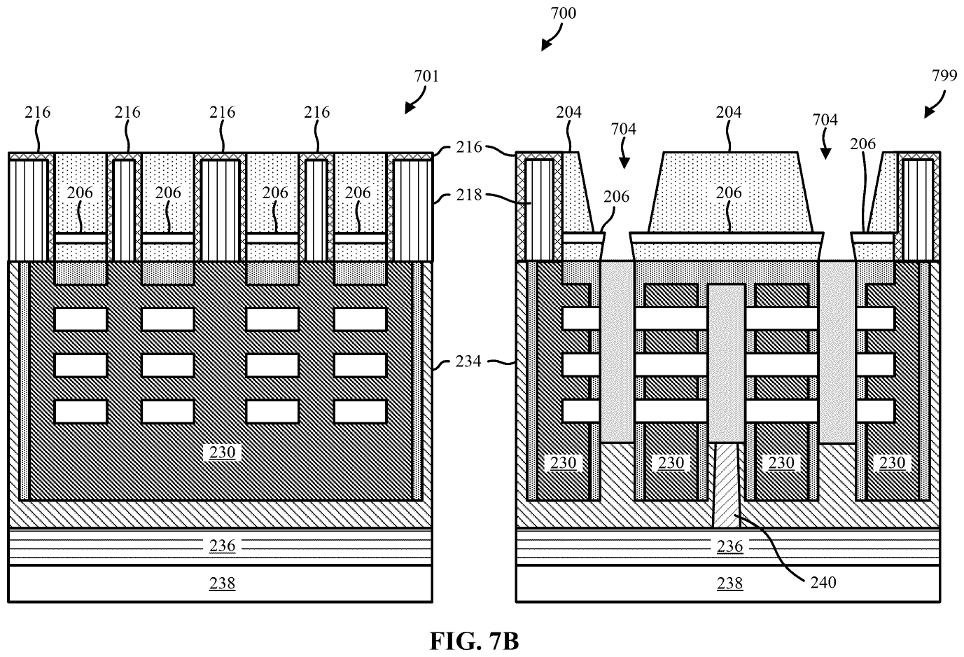

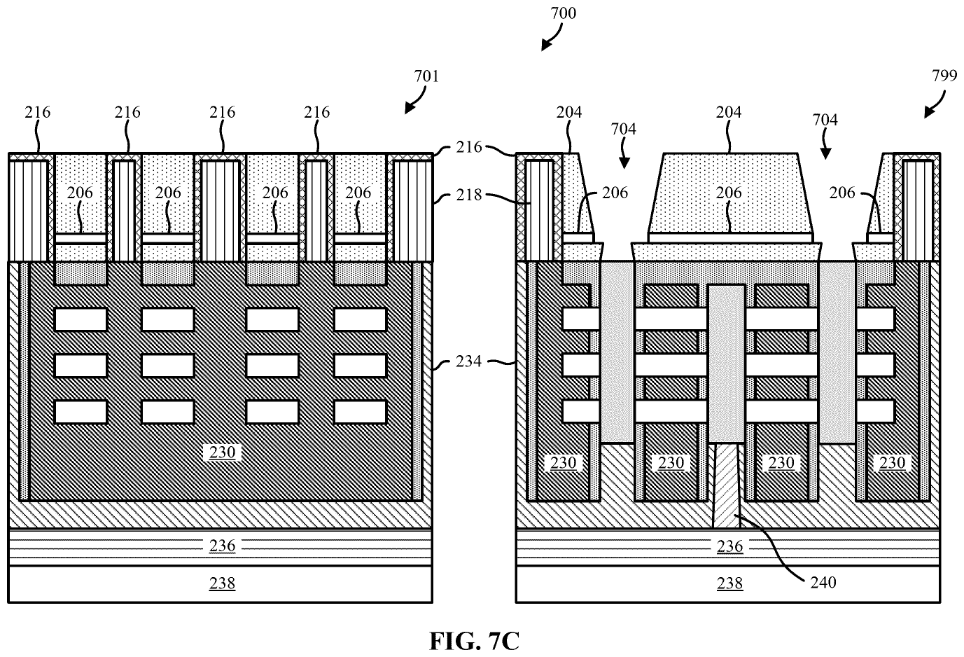

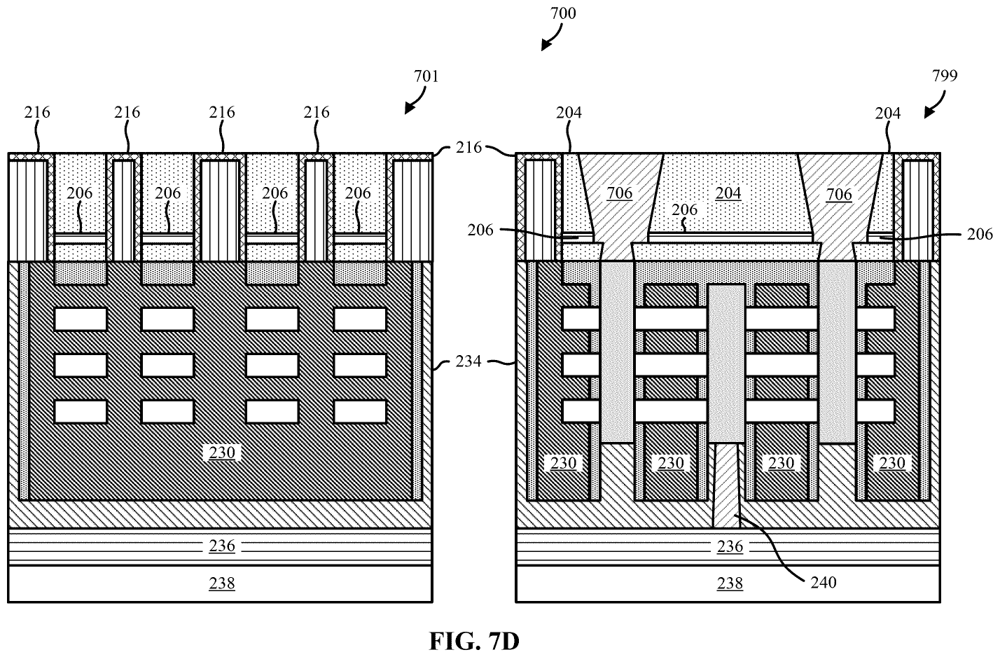

In a fifth embodiment of the present disclosure, the etch stop of the semiconductor device is at least partially removed to create a larger opening for the backside metal fill. Otherwise, the fifth embodiment is substantially similar to the first embodiment. FIGS. 7A-7D illustrate a process of fabricating an example of the fifth embodiment.

It is to be understood that as used herein, “an embodiment” means one or more embodiments that share a common aspect. For example, “a first embodiment” may include one or more embodiments that are related in that they all share a first common aspect, function, and/or feature. Likewise, “a second embodiment” may include one or more embodiments that are related in that they all share a second common aspect, function, and/or feature. Furthermore, a particular embodiment that has both the first common aspect, function, and/or feature and the second common aspect, function, and/or feature may be considered to be both a first embodiment and a second embodiment.

Embodiments of the present disclosure further include a method of manufacturing a semiconductor device. The method comprises forming a substrate with an embedded etch stop layer in BOX. The method further comprises patterning fin regions and filling the trenches with dielectric to create a composite stack and define the pattern for self-aligned backside connections. The method further comprises etching the source/drain regions. The method further comprises patterning and etching below the source/drain regions in selected areas below the etch stop layer (for future backside connection). The method further comprises backfilling the etched regions with temporary material in selected regions below the active channels. The method further comprises forming the source/drain epitaxy, gates, middle-of-line (MOL), and back-end-of-line (BEOL).

The method further comprises flipping and bonding a carrier wafer to the semiconductor device. The method further comprises removing the top substrate material to expose the frontside defined isolation regions. The method further comprises selectively removing the BOX region and temporary fill material to expose the source/drain bottom. The method further comprises forming metal rails with connections to the source/drain bottom. The method further comprises forming the BSPDN with connection to the rails and finish wafer processing.

Embodiments of the present disclosure provide a number of advantages over current technologies. For example, the frontside defined backside power and ground rails are connected to the bottom of the source/drain epitaxy without any critical patterning on the backside. This direct contact, utilizing an etch stop layer, provides self-aligned connections, has better process margin, reduces the complexity by requiring no critical level backside patterning, improves source/drain etch and fill aspect ratio, and enables full backside merged power rails for reduced resistance and increased performance. For example, the direct connection to the bottom of the source/drain epitaxy can shrink the library height by approximately 30-40 nm.

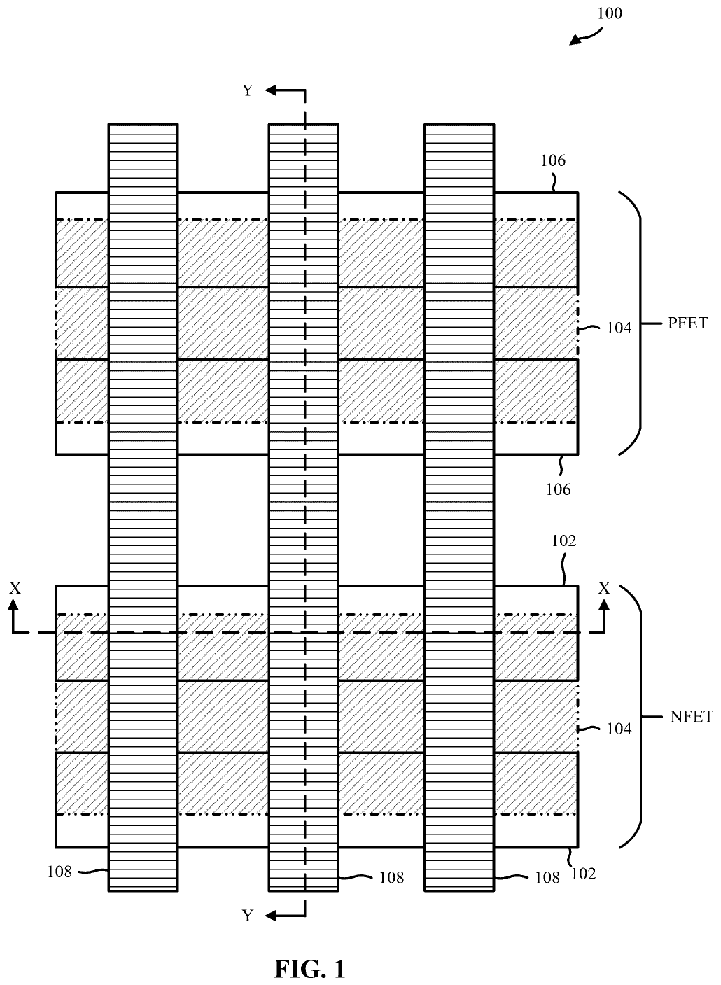

Turning now to the figures, FIG. 1 depicts a plan view of an example semiconductor device 100 indicating a Y cross-section location and an X cross section location for the following figures, in accordance with embodiments of the present disclosure. The semiconductor device 100 includes a NFET region disposed next to a PFET region. Metal gates 108 cross the NFET and PET regions. The NFET region includes two NFET nanosheet transistors 102 and a backside power rail (BPR) 104. Likewise, the PFET region includes two PFET nanosheet transistors 106 and a BPR 104. As such, FIG. 1 shows four nanosheet transistors (2 PFET and 2 NFET transistors).

Furthermore, complementary pairs of PFET nanosheet transistors and NFET nanosheet transistors may be coupled together to create one or more CMOS cells. For example, the NFET transistor at the top of the NFET region may be paired with the PFET transistor at the bottom of the PFET region to create a CMOS cell.

The BPRs 104 may lie on a different level of the semiconductor device 100 and substantially overlap the NFET nanosheet transistors 102 and the PFET nanosheet transistors 106. In other words, the BPR 104 may be below (for example) the NFETs and PFETs, as is illustrated by the dashed-and-dotted lines representing the edges of the BPR 104 substantially overlapping with the nanosheet transistors 102, 106.

FIG. 1 also shows the location of the cross-sectional cuts that are illustrated in FIGS. 2A-7D. Cut Y runs across the nanosheet transistors in the gate region, and cut X runs along a length of a single nanosheet 102 and crosses three gates 108. The subsequent figures show cross-sectional views along these cuts Y and X after particular fabrication operations.

Turning now to FIGS. 2A-7D, shown are fabrication processes for fabricating a semiconductor device having a self-aligned backside contact integration, in accordance with various embodiments. In particular, FIGS. 2A-7D show the semiconductor device at various stages in the process and in different embodiments. For example, FIGS. 2A-2K show the semiconductor device 100 of FIG. 1 during fabrication in accordance with a first embodiment, with each figure building on the previous (e.g., FIG. 2B shows the semiconductor device of FIG. 2A after one or more additional fabrication operations have been performed). Additionally, figures that share the same number (e.g., FIG. 2A, FIG. 2B, and FIG. 2C) show the semiconductor device according to the same embodiment.

Furthermore, each figure shows two different regions associated with the two cuts discussed above. In particular, each figure has a cross-sectional view of the across-gate, or nanosheet, region (e.g., across-gate region 201, which follows cut X) shown on the left and a cross-section view of the gate region (e.g., gate region 299, which follows cut Y) shown on the right.

Referring now to FIG. 2A, illustrated is a cross-sectional view of an example semiconductor device 200 at an intermediate stage in the fabrication process, in accordance with embodiments of the present disclosure. In particular, FIG. 2A illustrates the semiconductor device 200 after the formation of an initial, or starting, semiconductor stack on a wafer. The semiconductor stack comprises a BOX SiO₂ layer 204 deposited on top of a substrate 202. The thickness of the BOX layer can be varied depending on the desired process margins. An etch stop is embedded within the BOX layer 204 uniformly across the wafer. The etch stop 206 can be positioned within the BOX layer 204 based on the desired process/performance tradeoff (e.g., higher performance, with worse process or vice versa).

A first sacrificial layer 208 is deposited on top of the BOX layer 204. The first sacrificial layer 208 may be, for example, a sacrificial high-Ge % SiGe such as, for example, SiGe55%. Alternating layers of a second sacrificial material 210 and a semiconductor (e.g., Si) 212 may then be stacked on top of the first sacrificial material layer 208. The second sacrificial layer 210 may be a sacrificial low-Ge % SiGe layer such as, for example, SiGe25%. The layers of the semiconductor 212 will end up being the nanosheet layers that make up the semiconductor channel for the semiconductor device 200.

After creating the nanosheet stack, a hardmask may be deposited on a portion of the stack. After depositing the hardmask on the semiconductor device 200, the nanosheet stack may be patterned. This is shown in FIG. 2B. Patterning the nanosheet stack may include performing, for example, an extreme ultraviolet lithography (EUV) and/or an RIE operation to create a plurality of nanosheet structures (referred to herein as fins) separated by trenches 214 in the nanosheet region 201.

Additionally, backside contact isolation regions (also referred to herein simply as “isolation regions”) may be formed for guiding the self-aligned backside contacts. The isolation regions may be formed in both the nanosheet region 201 and the gate region 299 of the semiconductor device 200. The isolation regions may comprise a liner material 216 with an oxide fill 218. The liner may be, for example, SiN. The isolation regions may further act as shallow trench isolation (STI) layers in portions of the BOX layer 204 that are lateral to the patterned fins. The STI may prevent electric current leakage between the adjacent semiconductor components (e.g., between adjacent nanosheet FETs).

After forming the fins and the isolation regions, dummy gates 220 may be formed on the semiconductor device 200. This is shown in FIG. 2C. The dummy gates 220 may be made of any suitable material as would be recognized by a person of ordinary skill in the art. In some embodiments, the dummy gates 220 are a thin layer of SiO2 followed by bulk amorphous silicon (a-Si). A hardmask 222 may also be formed on top of the dummy gates 220. The dummy gates may be patterned using the hardmask, as shown in FIG. 2C.

Referring now to FIG. 2D, after forming the dummy gates 220 and hardmask 222, spacers 224 are deposited on top of the semiconductor device 200. The spacers 224 are then etched (e.g., using RIE) so that the spacers 224 are removed from the substantially horizontal surfaces (e.g., removed from the top of the hardmask 222 and the top of the top semiconductor layer 212) while remaining deposited along the sidewalls of the dummy gates 220 and the hardmask 222.

Additionally, the first sacrificial layer 208 may be selectively removed and replaced with the spacer material 224. In particular, the first sacrificial layer 208 may be selectively removed without removing the second sacrificial layers 210, and the first sacrificial layer 208 may be replaced with the spacer material 224 to create a bottom dielectric isolation (BDI) layer. The BDI layer may be that part of the spacer layers 224 that sit between the BOX layer 204 and the fins. As shown in FIG. 2D, the first sacrificial layer 208 may be removed from the entire semiconductor device 200, including the nanosheet region 201 and the gate region 299.

The spacer layers 224 may be made out of, for example, SiO2, SiOCN, SiOC, SiBCN. The spacer layers 224 may be deposited on the semiconductor device 200 after removal of the first sacrificial layer 208. In some embodiments, a spacer RIE operation may be performed to remove the spacer layer 414 from on top of the STIs 218 except along the sidewalls of the dummy gates 220.

After forming the one or more spacer layers 224, a nanosheet recess operation may be performed. This is shown in FIG. 2E. The nanosheet recess operation may include performing a selective etching operation that removes the portions of the second sacrificial layers 210, the semiconductor layers 212, and the BDI layer (e.g., bottom spacer 224 layer) that are not below the hardmask or spacers 224, resulting in a plurality of trenches 226. However, the spacer sidewalls 224 and the STI 218 are largely unaffected by the selective etching operation, though the spacer material may be etched such that it is slightly shorter and/or thinner than prior to etching. A result of the selective etching is that the top of the BOX layer 204 between the spacer sidewalls in the gate region 299 are exposed.

In FIG. 2E, the hardmask 222 and the spacer layers 224 act to largely protect the semiconductor stack below the hardmask 222 and the spacer layers 224, while the portion of the semiconductor stack between the spacer layers 224 are etched down into the BOX layer 204.

Referring now to FIG. 2F, an organic planarization layer (OPL) 228 is deposited on top of the semiconductor device 200. A self-aligned backside etch stop patterning is then performed to remove a portion of the BOX layer 204 and the etch stop 206 at the bottoms of the trenches 226. The etch stop 206 allows for reduced and well-controlled self-aligned etch depth.

Referring now to FIG. 2G, a temporary contact fill 242 is deposited into the trenches 226. The temporary contact fill 242 may be, for example, an oxide. In some embodiments, the temporary contact fill 242 is selected from a low-k dielectric material, SiN, or SiGe. A subsequent SiGe indentation operation is performed, resulting in exposed portions of the second sacrificial layers 210 in the trenches 226 being partially etched back. An inner spacer is then formed where the second sacrificial layers 210 were etched back. The inner spacer may be made out of, for example, SiO2, SiOCN, SiOC, SiBCN.

Next, a source/drain epitaxy 232 is grown in the trenches 226. The source/drain epitaxy 232 may be grown in the trenches 226 between the spacer sidewalls 224 in the gate region 299. A cyclic epi-etch back process may be used to ensure that the epi growth from exposed sidewalls of nanosheets can be suppressed. As shown in FIG. 2G, the source/drain epitaxy 232 extends above the top of the nanosheet stack. In other words, the top surface of the source-drain epitaxy 232 is above the top of the uppermost Si layer 212.

After growing the source/drain epitaxy 232, the second sacrificial layers 210 are released, a gate cut may be performed, and the HKMG layer 230 is formed on top of and around the remaining semiconductor material 212 in the gate region 299. In other words, during this stage, a replacement high-k metal gate is formed in place of each dummy gate 220 and SiGe layers 210. The HKMG layer 230 includes the high-k dielectric such as HfO2, ZrO, HfLaOx, HfAlOx, etc, and workfunction metal (WFM) such as TiN, TiC, TiAlC, TiAl, etc and it may further comprise optional low resistance conducting metals such as W, Co and Ru.

Those skilled in the art will recognize that a “replacement metal gate” refers to a gate, which replaces a previously formed dummy gate (also referred to herein as a sacrificial gate, a non-active gate, or a non-gate) and becomes an active component of the semiconductor structure being formed. The work function metal can comprise a metal selected so as to have a specific work function appropriate for a given type FET (e.g., an N-type FET or a P-type FET). For example, for a silicon-based N-type FET, the work function metal can comprise hafnium, zirconium, titanium, tantalum, aluminum, or alloys thereof, such as hafnium carbide, zirconium carbide, titanium carbide, tantalum carbide, or aluminum carbide, so that the work function metal has a work function similar to that of N-doped polysilicon. For a silicon-based P-type FET, the work function metal can comprise, for example, ruthenium, palladium, platinum, cobalt, or nickel, or a metal oxide (e.g., aluminum carbon oxide or aluminum titanium carbon oxide) or a metal nitride (e.g., titanium nitride, titanium silicon nitride, tantalum silicon nitride, titanium aluminum nitride, or tantalum aluminum nitride) so that the work function metal has a work function similar to that of P-doped polysilicon.

Next, the middle-of-line (MOL) and back-end-of-line (BEOL) 236 structures may be formed. The semiconductor device 200 may then be bonded to a carrier wafer 238. The MOL structures may include one or more epitaxy and/or gate contacts 240, as well as an inter-layer dielectric (ILD) 234 deposited on top of the semiconductor device 200 (e.g., as shown in FIG. 2G, in which an ILD 234 is on top of the metal gate 230). The epitaxy contact 240 may be made out of any suitable material including, for example, a silicide liner at bottom of the contact such as Ti, Ni, NiTi, NiPt, and a conductive metal such as Ru or W, or Co, with a thin adhesion metal liner such as TiN. The BEOL 236 may include a number of interconnects or other structures.

It is to be understood that the dimensions of the MOL and BEOL 236 structures, as well as the carrier wafer 238, are not necessarily drawn to scale. The MOL and BEOL 236 structures and the carrier wafer 238 may be formed using any suitable processes, as would be recognized by a person of ordinary skill in the art. In some embodiments, BEOL 236 and carrier wafer 238 may be pre-fabricated and then bonded with the semiconductor device 200.

The ILD 234 may surround and cover the source/drain epitaxy 232, the STI 218, the liner 216, the spacer sidewalls 224, and the metal gate 230 in the gate region 299, as shown in FIG. 2G. The ILD 234 can include any suitable material(s) known in the art, such as, for example, porous silicates, carbon doped oxides, silicon dioxides, silicon nitrides, silicon oxynitrides, or other dielectric materials. The ILD 234 can be formed using any method known in the art, such as, for example, chemical vapor deposition, plasma enhanced chemical vapor deposition, atomic layer deposition, or physical vapor deposition.

Next, the wafer is flipped and the substrate 202 is removed. This is shown in FIG. 2H. The substrate 202 may be removed through a selective etching process that stops on the BOX layer 204, which acts as an etch stop. After flipping the wafer, the BOX layer 204 that is below (above in the flipped image) the etch stop 206 is removed, thereby exposing the etch stop. Additionally, the temporary fill 242 is removed. This is shown in FIG. 2I.

Backside contact metallization is then performed. This is shown in FIG. 2J. the backside contact metallization operation may comprise a precontact clean followed by depositing a conductive backside contact 243 and performing a CMP process. The CMP process may planarize the top of the semiconductor device 200 such that the top of the conductive backside contact 243 is coplanar with the top of the liner 216.

The conductive backside contact 243 may be formed of any suitable conductive material such as, for example, a silicide liner at the bottom of the contact such as Ti, Ni, NiTi, NiPt, and a conductive metal fill such as Ru or W, or Co, with a thin adhesion metal liner such as TiN.

Next, an ILD 248 may be formed on top of the conductive backside contact 243. This is shown in FIG. 2K. Backside vias and wires are then formed in the ILD 248. In particular, BPRs 244 may then be formed in the ILD 248. The BPRs 244 may include a Vss and a Vdd BPR. The Vdd BPR may be formed at least partially on top of the conductive backside contact 243. In particular, the BPR 244 is formed such that it is in contact with two of the conductive backside contacts 243 in the nanosheet region 201. For example, the BPR 244 may bridge the conductive backside contacts 243 for adjacent NFETs, as shown in FIG. 2K. The BSPDN 246 is then formed on top of the BPRs 244.

As shown in FIG. 2K, the backside contacts 243 are self-aligned. In particular, the backside contacts have a self-aligned contact 250 with the source/drain epitaxy and a self-alignment 252 with the STIs 218.

Turning now to FIGS. 3A-3C, shown are cross-sectional views of a semiconductor device 300 at various stages in the fabrication process, in accordance with some embodiments of the present disclosure. As with FIGS. 2A-2K, FIGS. 3A-3C show cross-section views of the nanosheet region 301 and the gate region 399 of the semiconductor device 300. The fabrication process shown in FIGS. 3A-3C are substantially similar to those shown in FIGS. 2A-2K. Accordingly, only operations or structures that differ from those shown in FIGS. 2A-2K are illustrated in FIGS. 3A-3C.

Following the formation of the nanosheet stack (e.g., as shown in FIG. 2A), the backside contact isolation regions (also referred to herein simply as “isolation regions”) may be formed for guiding the self-aligned backside contacts. This is shown in FIG. 3A. The isolation regions may be formed in both the nanosheet region 301 and the gate region 399 of the semiconductor device 300. The isolation regions may comprise a liner material 216 with an oxide fill 218. The liner may be, for example, SiN. The isolation regions may further act as shallow trench isolation (STI) layers in portions of the BOX layer 204 that are lateral to the patterned fins. The STI may prevent electric current leakage between the adjacent semiconductor components (e.g., between adjacent nanosheet FETs).

The isolation regions shown in FIG. 3A may be formed in substantially the same way as the isolation regions were formed in FIG. 2B. In other words, the semiconductor device 300 shown in FIG. 3A may be an alternative embodiment from the semiconductor device 200 shown in FIG. 2B. The difference between the semiconductor device 300 and the semiconductor device 200 is that some of the isolation regions of the semiconductor device 300 do not extend all the way down to the substrate. In particular, the isolation regions separating adjacent NFETs may only extend partially into the BOX layer 204. Similarly, the isolation regions separating adjacent PFETs may only extend partially into the BOX layer 204. Meanwhile, the isolation regions separating an NFET from an adjacent PFET may extend all the way through the BOX layer 204 to the substrate 202, as shown in FIG. 3A.

Referring now to FIG. 3B, shown is the semiconductor device 300 after backside contact metallization has been performed. In other words, the semiconductor device 300 shown in FIG. 3B is at substantially the same stage as the semiconductor device 200 shown in FIG. 2J. However, as shown in FIG. 3B, the metallization operation results in conductive backside contacts 243 that are shared/merged in the nanosheet region 301. This occurs because the isolation regions did not extend all the way through the BOX layer 204 in FIG. 3A. In particular, as shown in FIG. 3B, the conductive backside contacts 243 for adjacent NFETs are merged in the nanosheet region 301, as are the conductive backside contacts 243 for adjacent PFETs.

Next, an ILD 248 may be formed on top of the conductive backside contact 243. This is shown in FIG. 3C. BPRs 244 may then be formed in the ILD 248. The BPRs 244 may include a Vss and a Vdd BPR. The BPR 244 may be formed at least partially on top of the conductive backside contact 243. The BSPDN 246 is then formed on top of the BPRs 244.

Turning now to FIGS. 4A-4B, shown are cross-sectional views of a semiconductor device 400 at various stages in the fabrication process, in accordance with some embodiments of the present disclosure. As with FIGS. 2A-2K, FIGS. 4A-4B show cross-section views of the nanosheet region 401 and the gate region 499 of the semiconductor device 400. The fabrication process shown in FIGS. 4A-4B is substantially similar to the fabrication process shown in FIGS. 2A-2K. Accordingly, only operations or structures that differ from those shown in FIGS. 2A-2K are illustrated in FIGS. 4A-4B.

Following the wafer flip and removal of the substrate 202 (e.g., as shown in FIG. 2H), the BOX layer 204 may be selectively etched above the temporary contact fill 242 and the temporary contact fill 242 may be removed to create trenches 402. This is shown in FIG. 4A. The semiconductor device 400 shown in FIG. 4A is an alternative to the semiconductor device 200 shown in FIG. 2I, with the difference relating to the amount of the BOX layer that is removed. In other words, unlike the semiconductor device 200 shown in FIG. 2I, in which the entire BOX layer 204 was removed along with the temporary contact fill 242, in the semiconductor device 400 shown in FIG. 4A, only portions of the BOX layer 204 are removed.

Next, the backside contact metallization is performed to create backside contacts 404 in the trenches 402. This is shown in FIG. 4B. Following the creation of the backside contacts 404, the BPRs 244 and BSPDN 246 may be formed in substantially the same manner described above.

Turning now to FIGS. 5A-5I, shown are fabrication processes for fabricating a semiconductor device 500 having a self-aligned backside contact integration, in accordance with various embodiments. In particular, FIGS. 5A-5I show the semiconductor device 500 at various stages in the process and in different embodiments. The semiconductor device 500 and the process shown in FIGS. 5A-5I is substantially similar to the semiconductor device 200 and process shown in FIGS. 2A-2J. However, the semiconductor device 500 shows an embodiment where there is a bulk substrate (e.g., Si layer 504) with the etch stop 506 on top of the bulk substrate.

Referring now to FIG. 5A, illustrated is a cross-sectional view of an example semiconductor device 500 at an intermediate stage in the fabrication process, in accordance with embodiments of the present disclosure. In particular, FIG. 5A illustrates the semiconductor device 500 after the formation of an initial, or starting, semiconductor stack on a wafer. The semiconductor stack comprises a Silayer 504 deposited on top of a substrate 502. The thickness of the Si layer can be varied depending on the desired process margins. An etch stop layer 506 is deposited on top of the Si layer 504 uniformly across the wafer. The etch stop layer 506 can be a BDI.

A first sacrificial layer 508 is deposited on top of the etch stop layer 506. The first sacrificial layer 508 may be, for example, a sacrificial high-Ge % SiGe such as, for example, SiGe55%. Alternating layers of a second sacrificial material 510 and a semiconductor (e.g., Si) 512 may then be stacked on top of the first sacrificial material layer 508. The second sacrificial layer 510 may be a sacrificial low-Ge % SiGe layer such as, for example, SiGe25%. The layers of the semiconductor 512 will end up being the nanosheet layers that make up the semiconductor channel for the semiconductor device 500.

Referring now to FIG. 5B, after creating the nanosheet stack, additional fabrication processes that are substantially similar to those described with reference to FIGS. 2B-2E are performed. For the sake of brevity, the specifics of these steps are omitted. The resulting semiconductor device 500 includes backside contact isolation regions for guiding the self-aligned backside contacts. The isolation regions may be formed in both the nanosheet region 501 and the gate region 599 of the semiconductor device 500. The isolation regions may comprise a liner 516 with an oxide fill 518. The liner may be, for example, SiN. The isolation regions may further act as shallow trench isolation (STI) layers in portions of the Si layer 504 that are lateral to the patterned fins. The STI may prevent electric current leakage between the adjacent semiconductor components (e.g., between adjacent nanosheet FETs).

The semiconductor device 500 may further include dummy gates 520. The dummy gates 520 may be made of any suitable material as would be recognized by a person of ordinary skill in the art. In some embodiments, the dummy gates 520 are a thin layer of SiO2 followed by bulk amorphous silicon (a-Si). A hardmask 522 may also be formed on top of the dummy gates 520. The dummy gates may be patterned using the hardmask.

The semiconductor device 500 further includes spacers 524. The spacers 524 may be deposited on top of the semiconductor device 500 and then etched (e.g., using RIE) so that the spacers 524 are removed from the substantially horizontal surfaces (e.g., removed from the top of the hardmask 522 and the top of the top semiconductor layer 512) while remaining deposited along the sidewalls of the dummy gates 520 and the hardmask 522.

Additionally, the first sacrificial layer 508 may be selectively removed and replaced with the spacer material 524. In particular, the first sacrificial layer 508 may be selectively removed without removing the second sacrificial layers 510, and the first sacrificial layer 508 may be replaced with the spacer material 524 to create a BDI layer. The BDI layer may be that part of the spacer layers 524 that sit between the Si layer 504 and the fins.

The spacer layers 524 may be made out of, for example, SiO2, SiOCN, SiOC, SiBCN. The spacer layers 524 may be deposited on the semiconductor device 500 after removal of the first sacrificial layer 508. In some embodiments, a spacer RIE operation may be performed to remove the spacer layer 524 from on top of the STIs 518 except along the sidewalls of the dummy gates 520.

After forming the one or more spacer layers 524, a nanosheet recess operation may be performed. The nanosheet recess operation may include performing a selective etching operation that removes the portions of the second sacrificial layers 510, the semiconductor layers 512, the BDI layer (e.g., bottom spacer 524 layer), and the Si layer 504 that are not below the hardmask or spacers 524, resulting in a plurality of trenches 526. However, the spacer sidewalls 524 and the STI 518 are largely unaffected by the selective etching operation, though the spacer material may be etched such that it is slightly shorter and/or thinner than prior to etching. A result of the selective etching is that the top of the substrate 502 between the spacer sidewalls in the gate region 599 is exposed.

Additionally, as shown in FIG. 5B, an organic planarization layer (OPL) 528 is deposited on top of the semiconductor device 500. A self-aligned backside etch stop patterning is then performed to remove a portion of the Si layer 504 and the etch stop 506 at the bottoms of the trenches 526. In particular, the Si layer 504 is removed down to the substrate 502.

Referring now to FIG. 5C, shown in the semiconductor device 500 after performance of additional fabrication operation, which are substantially similar to those discussed above with respect to FIGS. 2A-2K and have been omitted for brevity. The semiconductor device 500 includes temporary contact fill 542 deposited at the bottom of the trenches 526 (shown in FIG. 5B). The temporary contact fill 542 may be, for example, an oxide. In some embodiments, the temporary contact fill 542 is selected from a low-k dielectric material, SiN, or SiGe. A subsequent SiGe indentation operation is performed, resulting in exposed portions of the second sacrificial layers 510 in the trenches 526 being partially etched back. An inner spacer 524 is then formed where the second sacrificial layers 510 were etched back. The inner spacer may be made out of, for example, SiO2, SiOCN, SiOC, SiBCN.

Next, a source/drain epitaxy 540 is grown in the trenches 526. The source/drain epitaxy 540 may be frown in the trenches 526 between the spacer sidewalls 524 in the gate region 599. A cyclic epi-etch back process may be used to ensure that the epi growth from exposed sidewalls of nanosheets can be suppressed. As shown in FIG. 5C, the source/drain epitaxy 540 extends above the top of the nanosheet stack. In other words, the top surface of the source-drain epitaxy 540 is above the top of the uppermost Si layer 512.

After growing the source/drain epitaxy 540, the second sacrificial layers 510 are released, a gate cut is performed, and the HKMG layer 530 is formed on top of and around the remaining semiconductor material 512 in the gate region 599. In other words, during this stage, a replacement high-k metal gate is formed in place of each dummy gate 520 and SiGe layers 510. The HKMG layer 530 includes the high-k dielectric such as HfO2, ZrO, HfLaOx, HfAlOx, etc, and workfunction metal (WFM) such as TiN, TiC, TiAlC, TiAl, etc and it may further comprise optional low resistance conducting metals such as W, Co and Ru.

Those skilled in the art will recognize that a “replacement metal gate” refers to a gate, which replaces a previously formed dummy gate (also referred to herein as a sacrificial gate, a non-active gate, or a non-gate) and becomes an active component of the semiconductor structure being formed. The work function metal can comprise a metal selected so as to have a specific work function appropriate for a given type FET (e.g., an N-type FET or a P-type FET). For example, for a silicon-based N-type FET, the work function metal can comprise hafnium, zirconium, titanium, tantalum, aluminum, or alloys thereof, such as hafnium carbide, zirconium carbide, titanium carbide, tantalum carbide, or aluminum carbide, so that the work function metal has a work function similar to that of N-doped polysilicon. For a silicon-based P-type FET, the work function metal can comprise, for example, ruthenium, palladium, platinum, cobalt, or nickel, or a metal oxide (e.g., aluminum carbon oxide or aluminum titanium carbon oxide) or a metal nitride (e.g., titanium nitride, titanium silicon nitride, tantalum silicon nitride, titanium aluminum nitride, or tantalum aluminum nitride) so that the work function metal has a work function similar to that of P-doped polysilicon.

Next, the middle-of-line (MOL) and back-end-of-line (BEOL) 534 structures may be formed. The semiconductor device 500 may then be bonded to a carrier wafer 536. The MOL structures may include one or more epitaxy and/or gate contacts 538, as well as an inter-layer dielectric (ILD) layer 532 deposited on top of the semiconductor device 500. The epitaxy contact 538 may be made out of any suitable material including, for example, a silicide liner at bottom of the contact such as Ti, Ni, NiTi, NiPt, and a conductive metal such as Ru or W, or Co, with a thin adhesion metal liner such as TiN. The BEOL 534 may include a number of interconnects or other structures.

It is to be understood that the dimensions of the MOL and BEOL 534 structures, as well as the carrier wafer 536, are not necessarily drawn to scale. The MOL and BEOL 534 structures and the carrier wafer 536 may be formed using any suitable processes, as would be recognized by a person of ordinary skill in the art. In some embodiments, BEOL 534 and carrier wafer 536 may be pre-fabricated and then bonded with the semiconductor device 500.

The ILD 532 may surround and cover the source/drain epitaxy 540, the STI 518, the liner 516, the spacer sidewalls 524, and the metal gate 530 in the gate region 599, as shown in FIG. 5C. The ILD 532 can include any suitable material(s) known in the art, such as, for example, porous silicates, carbon doped oxides, silicon dioxides, silicon nitrides, silicon oxynitrides, or other dielectric materials. The ILD 532 can be formed using any method known in the art, such as, for example, chemical vapor deposition, plasma enhanced chemical vapor deposition, atomic layer deposition, or physical vapor deposition.

Next, the wafer is flipped and the substrate 502 is removed. This is shown in FIG. 5D. The substrate 502 may be removed through a selective etching process that stops on the Si layer 504, which acts as an etch stop. After flipping the wafer, a lithography mask 544 is deposited on top of the semiconductor device 500. This is shown in FIG. 5E. In particular, the lithography mask 544 is deposited over the Si layer 504 and the liner 516. However, the temporary fill 542 remains exposed (e.g., uncovered) by the lithography mask 544.

After the lithography mask 544 is deposited on the semiconductor device 500, the temporary fill 542 is removed. This is shown in FIG. 5F. The resulting semiconductor device 500 has trenches 546 formed directly below (above in the figure) the source/drain epitaxy 540. Next, backside contacts 548 are formed in the trenches 546 left behind by the temporary fill 542. This is shown in FIG. 5G. The backside contacts 548 are formed by a backside contact metallization operation that may comprise a precontact clean followed by depositing a conductive backside contact 548 on the source/drain epitaxies 540 and performing a CMP process. The CMP process may planarize the top of the semiconductor device 500 such that the top of the conductive backside contact 548 is coplanar with the top of the liner 516 and the remaining Si layer 504. The conductive backside contacts 548 may be formed of any suitable conductive material such as, for example, a silicide liner at the bottom of the contact such as Ti, Ni, NiTi, NiPt, and a conductive metal fill such as Ru or W, or Co, with a thin adhesion metal liner such as TiN.

Following formation of the backside contacts 548, the Si layer 504 is recessed. This is shown in FIG. 5H. A low-k dielectric 550 is then formed where the Si layer 504 previously existed. This is shown in FIG. 5I. In some embodiments, the low-k dielectric 550 is deposited such that air gaps 552 are formed in at least a portion of the low-k dielectric 550 as well. In some embodiments, the etch stop layer is removed prior to deposition of the low-k dielectric 550. This is shown in FIG. 6. The etch stop layer may be removed using any suitable etching technique, as would be understood by a person of ordinary skill in the art.

Turning now to FIGS. 7A-7D, shown are cross-sectional views of a semiconductor device 700 at various stages in the fabrication process, in accordance with some embodiments of the present disclosure. As with FIGS. 2A-2K, FIGS. 7A-7D show cross-section views of the nanosheet region 701 and the gate region 799 of the semiconductor device 700. The fabrication process shown in FIGS. 7A-7D are substantially similar to those shown in FIGS. 2A-2K. Accordingly, only operations or structures that differ from those shown in FIGS. 2A-2K are illustrated in FIGS. 7A-7D.

Referring first to FIG. 7A, shown in the semiconductor device 700 after the formation of the BEOL 236 and binding of the carrier wafer 238. In other words, FIG. 7A shows the semiconductor device 700 following performance of the operations discussed with respect to FIGS. 2A-2G. As such, FIG. 7A is substantially similar to FIG. 2G, with the only difference being that the temporary fill 702 shown in FIG. 7A has a different shape than the temporary fill 242 shown in FIG. 2G. In particular, the temporary fill 702 has a trapezoidal shape, as opposed to the rectangular shape of the temporary fill 242, due to real-world limitations of the etching process used to create the region occupied by the temporary fill 702.

The shape of the temporary fill 702 may not be suitable for backside metal fill (e.g., metallization). Accordingly, after flipping the wafer and removing the substrate 202, the BOX layer 204 may be selectively etched (e.g., using RIE) to remove portions of the BOX layer 204 below the temporary fill 702. This is shown in FIG. 7B. The selective etching of the BOX layer 204 results in trenches 704 disposed above the now exposed source/drain epitaxies. The RIE may be selective to (i.e., stop at) the etch stop 206.

Next, the exposed portions of the etch stop 206 are removed. This is shown in FIG. 7C. As can be seen in FIG. 7C, only those portions of the etch stop 206 that were exposed by the etching of the BOX layer 204 may be removed. After removal of a portion of the etch stop 206, the backside contacts 706 are formed. This is shown in FIG. 7D. The partial removal of the etch stop 206 may result in an easier metal fill by increasing the width of the trench in which the backside contacts 706 are formed.

It is to be understood that the aforementioned advantages are example advantages and should not be construed as limiting. Embodiments of the present disclosure can contain all, some, or none of the aforementioned advantages while remaining within the spirit and scope of the present disclosure.

Detailed embodiments of the structures of the present invention are described herein. However, it is to be understood that the embodiments described herein are merely illustrative of the structures that can be embodied in various forms. In addition, each of the examples given in connection with the various embodiments of the invention is intended to be illustrative, and not restrictive. Further, the figures are not necessarily to scale, some features can be exaggerated to show details of particular components. Therefore, specific structural and functional details described herein are not to be interpreted as limiting, but merely as a representative basis for teaching one skilled in the art to variously employ the methods and structures of the present description

It should also be understood that material compounds will be described in terms of listed elements, e.g., SiN, SiCN, SiCO, or SiGe. These compounds include different proportions of the elements within the compound, e.g., SiGe includes SiₓGe₍₁₋ₓ₎ where x is less than or equal to 1, and the like. In addition, other elements can be included in the compound and still function in accordance with the present principles. The compounds with additional elements will be referred to herein as alloys.

It should be noted that not all masking, patterning, and lithography processes are shown because a person of ordinary skill in the art would recognize where masking and patterning processes are utilized to form the identified layers and openings, and to perform the identified selective etching processes, as described herein.

As discussed herein, embodiments of the present disclosure include a method. The method may be performed by, for example, a computer system that controls semiconductor fabrication machinery. As such, the method may be embodied as a computer program product having software instructions on a storage medium. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device comprising:
a plurality of logic devices with frontside wiring;
a backside power delivery network (BSPDN); and
a connection between the BSPDN and the bottom of a source/drain epitaxy of a logic device, wherein the connection is self-aligned on at least two sides.

2. The semiconductor device of claim 1, wherein the connection is a ground or power rail that connects the source/drain epitaxies from multiple logic devices to the BSPDN.

3. The semiconductor device of claim 2, wherein the multiple logic devices are in the same library track.

4. The semiconductor device of claim 2, wherein the multiple logic devices are in adjacent library tracks.

5. The semiconductor device of claim 2, wherein the power or ground rail is shared by two adjacent logic devices of the same polarity.

6. The semiconductor device of claim 5, wherein the two adjacent logic devices are NFET nanosheet transistors.

7. The semiconductor device of claim 2, wherein perimeter edges of the ground or power rail are defined by frontside patterned isolation regions.

8. The semiconductor device of claim 7, wherein the frontside patterned isolation regions are shallow trench isolation (STI) regions under channels of the plurality of logic devices.

9. The semiconductor device of claim 2, further comprising a bottom dielectric isolation (BDI) layer under gates of the plurality of logic devices.

10. The semiconductor device of claim 2, further comprising a bulk semiconductor region below the plurality of logic devices and at the same level as the power or ground rails.

11. The semiconductor device of claim 1, wherein the connection is a backside contact.

12. The semiconductor device of claim 11, wherein two sides of the backside contact are defined by frontside patterned isolation regions.

13. The semiconductor device of claim 12, further comprising a pre-formed BOX layer, the pre-formed BOX layer separating the backside contact on two sides from the frontside patterned isolation regions.

14. The semiconductor device of claim 11, wherein the backside contact bridges two power or ground rails of adjacent logic devices of the same polarity.

15. A semiconductor device comprising:
a plurality of nanosheet transistors, each nanosheet transistor including a source/drain epitaxy;
a backside power delivery network (BSPDN);
a connection between the BSPDN and the bottom of a source/drain epitaxy of a nanosheet transistor, wherein the connection is self-aligned on at least two sides;
a back-end-of-line (BEOL) structure; and
one or more BEOL contacts, each of the one or more BEOL contacts connecting a source/drain epitaxy of a nanosheet transistor to the BEOL.

16. The semiconductor device of claim 15, further comprising an inter-layer dielectric (ILD) between the nanosheet transistors and the BEOL, wherein the one or more BEOL contacts are formed in the ILD.

17. A method of fabricating a semiconductor device, the method comprising:
forming a substrate with a BOX layer that includes an etch stop;
patterning fin regions and filling with dielectric composite stack to create one or more isolation regions that define a pattern for one or more self-aligned backside connections;
forming one or more nanosheet transistors in the dielectric composite stack;
removing the substrate to expose the one or more isolation regions;
selectively removing at least a portion of the BOX layer to expose the bottom of a source/drain epitaxy of at least one nanosheet transistor; and
forming metal rails with connections to the bottom of the source/drain epitaxy in the region opened up by removal of the portion of the BOX layer.

18. The method of claim 17, wherein the etch stop is formed on top of the BOX layer.

19. The method of claim 17, wherein forming the one or more nanosheet transistors in the dielectric composite stack comprises:
etching the dielectric composite stack to create a plurality of source/drain regions;
selectively patterning and etching below the source/drain regions below the etch stop to create a void below one or more source/drain regions that are below an active channel;
filling the voids with a temporary material;
forming a source/drain epitaxy in the source/drain regions;
forming gates of the nanosheet transistors; and
forming middle-of-line (MOL) and back-end-of-line (BEOL) structures.

20. The method of claim 19, further comprising:
forming a backside power delivery network with connection to the metal rails.
